(19) United States
(12) Patent Application Publication
(10) Pub. No.: US 2026/0340234 A1
(43) Pub. Date: Oct. 29, 2026

(54) Automated Systems for Power Outage Restoration

(71) Applicant: University of Connecticut, Farmington, CT (US)

(72) Inventors: Diego Cerrai, Stafford Springs, CT (US); Chirag Mehta, Vernon, CT (US); Aaron Spaulding, Windsor, CT (US); Tara Walsh, Boylston, MA (US)

(73) Assignee: University of Connecticut, Farmington, CT (US)

(21) Appl. No.: 19/659,472

(22) Filed: Apr. 27, 2026

Related U.S. Application Data
(60) Provisional application No. 63/795,599, filed on Apr. 27, 2025.

(51) Int. Cl. G06F 30/27

(52) U.S. Cl. CPC G06F 30/27

(57) ABSTRACT

The present disclosure relates to a system for planning a utility restoration process in a geographic region. The system includes an input layer, which includes outage management system (OMS) data, location data, work crew data, and actual outage data. The system further includes a core agent-based model (ABM) engine, including a simulation module communicatively coupled to the input layer and configured to simulate a plurality of work crews as a plurality of agents. Each agent is a state machine which represents a respective work crew of the plurality of work crews. The simulation module assigns each agent to repair a damaged component using either a reinforcement learning module or a graph neural network module. The core ABM engine generates an expected activity timetable and an expected restoration curve. The present disclosure additionally relates to a reinforcement learning module and a method of using a graph neural network.

### CROSS-REFERENCE TO RELATED APPLICATIONS

The present Application is a nonprovisional application and claims the benefit of United States Provisional Application Ser. No. 63/795,599 entitled “Automated System for Planning Power Outage Restoration,” filed on Apr. 27, 2025, the contents of which is incorporated herein by reference.

### BACKGROUND

### 1. Field of the Invention

The technology relates to infrastructure management and, in particular, to modeling and effectuating restoration of services due to power outages.

### 2. Description of the Related Art

Electrical distribution infrastructure includes interconnected systems of substations, transformers, distribution lines, and switching equipment that deliver electrical power from transmission systems to end users. This infrastructure supports residential, commercial, and industrial electrical loads. The infrastructure typically includes overhead and underground components distributed across urban, suburban, and rural areas. These components function as the terminal network for delivering regulated voltage and current to utility customers.

Major storms, including hurricanes, ice storms, and severe wind events, pose significant challenges to electrical distribution infrastructure. These events often result in mechanical damage to poles, conductors, insulators, and switching equipment. Falling trees, flooding, and debris obstruct access routes, further complicating restoration efforts. Regional outages caused by such storms can affect hundreds of thousands of customers, often resulting in large-scale restoration planning and coordination.

Completion of restoration services following a regional outage presents multiple complications. Restoration logistics often include prioritization of critical infrastructure, such as hospitals and water treatment facilities, and coordination of field crews, equipment, and replacement parts. Damage assessment often needs to occur before accurate restoration plans can be formulated. These damage assessments may include manual inspections under hazardous conditions. Communication of real-time restoration status to customers may be inconsistent due to variable field conditions and outdated tracking systems. Customers frequently receive incomplete or inaccurate information regarding estimated restoration times and service updates.

The complexity of regional restoration also impedes effective resource allocation. Utilities must coordinate across jurisdictions and, in many cases, request mutual aid from other regional utilities. Variability in regional grid architecture and operational protocols further delays restoration activities. Delayed communications between field crews, command centers, and customer support systems hinder transparency and prolong service interruptions.

Accordingly, improved systems are needed to enhance monitoring, decision-making, communications and repair/restoration services to electrical distribution networks, particularly in response to large scale power outages. These systems should support real-time situational awareness, automated fault detection, damage assessment, crew dispatch, and customer notifications. Integration of geospatial data, sensor telemetry, and predictive analytics may enhance restoration speed, efficiency, and reliability. Development of improved systems may reduce economic losses, mitigate public safety risks, and increase customer satisfaction during storm-related outages.

### SUMMARY

In accordance with one aspect of the disclosure, the present disclosure relates to a system for planning a utility restoration process in a geographic region. The system includes an input layer. The input layer includes outage management system (OMS) data. The OMS data represents a plurality of utility grid outages recorded during at least one previous storm. The input layer also includes location data. The location data represents a starting location of each work crew of the plurality of work crews. The input layer also includes work crew data. The work crew data represents a number of work crews in the plurality of work crews, and a working shift of each respective work crew of the plurality of work crews. The input layer additionally includes actual outage data. The actual outage data represents a plurality of damaged components of the utility grid. The system further includes a core agent-based model (ABM) engine, including a simulation module communicatively coupled to the input layer and configured to simulate the plurality of work crews as a plurality of agents. Each agent of the plurality of agents is a state machine which represents a respective work crew of the plurality of work crews. The simulation module assigns each agent of the plurality of agents to repair a damaged component of the plurality of damaged components using either a reinforcement learning module or a graph neural network module. The core ABM engine generates an expected activity timetable for the plurality of work crews that shows a plurality of activities that each agent takes to repair the plurality of damaged components. The core ABM engine also generates an expected restoration curve.

In accordance with another aspect of the disclosure, the present disclosure relates to a reinforcement learning (RL) module for generating repair assignments for a plurality of work crews during a utility restoration process in a geographic region. The RL module includes a core RL environment. The core RL environment generates a state analysis of the utility restoration process based on a plurality of agents which each represent each of the work crews of the plurality of work crews as a state machine. The state analysis is also based on outage management system (OMS) data, wherein the OMS data represents a plurality of utility grid outages recorded during at least one previous storm. The state analysis is additionally based on a storm profile including meteorological prediction of a storm impacting the geographic region.

The state analysis is further based on a state of the utility restoration process. The RL module also includes a RL agent which receives the state analysis from the core RL environment via a state encoder. The RL agent generates a vector of priority weights. The RL module further includes a spot scorer which receives the vector of priority weights via a state decoder, and a registry of trouble spots. The registry of trouble spots includes a list of a plurality of trouble spots located in the geographic region. The spot scorer assigns each agent of the plurality of agents to a trouble spot in the geographic region based on the vector of priority weights.

In accordance with another aspect of the present disclosure, the present disclosure relates to a method for generating work crew assignments for a plurality of work crews during a utility restoration process of a geographic region using a graph neural network (GNN) module. The method includes constructing a heterogenous graph structure including a plurality of nodes based on a registry of trouble spots. The registry of trouble spots includes a list of a plurality of trouble spots located in the geographic region. The heterogenous graph structure is also based on a plurality of agents which each represent each of the work crews of the plurality of work crews as a state machine. The heterogeneous graph structure is additionally based on an area work center registry which represents a plurality of area work centers located in the geographic region. The heterogeneous graph structure if further based on a travel matrix. The travel matrix includes a list of travel times between each of the plurality of trouble spots and each of the plurality of area work centers. The method also includes applying a message-passing algorithm such that each node of the plurality of nodes collects information from at least one immediately neighboring node of the plurality of nodes. The method additionally includes applying the message passing algorithm such that each node of the plurality of nodes collects information from at least one neighboring node of the at least one immediately neighboring node of the plurality of nodes. The method further includes applying an attention mechanism to at least one spot node of the plurality of nodes. The method also includes utilizing a per-agent weight head to output a priority weight vector specific to each agent of the plurality of agents. The method further includes utilizing a spot scorer to assign each agent of the plurality of agents to a trouble spot based on the priority weight vector of each agent of the plurality of agents.

These and other advantages and features will become more apparent from the following description taken in conjunction with the drawings.

### BRIEF DESCRIPTION OF THE DRAWINGS

The subject matter, which is regarded as the disclosure, is particularly pointed out and distinctly claimed in the claims at the conclusion of the specification. The foregoing and other features, and advantages of the disclosure are apparent from the following detailed description taken in conjunction with the accompanying drawings in which:

FIG. 1 is a workflow schematic of an Agent-Based-Model (“ABM”) according to some embodiments of the present disclosure;

FIG. 2 is a graph of affected customers after a storm;

FIG. 3 is a crew distribution chart generated by the ABM, according to some embodiments of the present disclosure;

FIG. 4 is a second crew distribution chart, according to some embodiments of the present disclosure;

FIG. 5 is a schematic view of the ABM according to some embodiments of the present disclosure;

FIG. 6 is a system architecture of a storm data generator of the ABM, according to some embodiments of the present disclosure;

FIG. 7 is a system architecture of a road network component of the ABM, according to some embodiments of the present disclosure;

FIG. 8 is a Reinforced Learning (“RL”) architecture of the ABM, according to some embodiments of the present disclosure;

FIG. 9 is a Social Vulnerability Index (“SoVI”) architecture of the RL module, according to some embodiments of the present disclosure;

FIG. 10 is a Graph Neural Network (“GNN”) architecture of the ABM, according to some embodiments of the present disclosure;

FIG. 11 is an optimization architecture of the ABM, according to some embodiments of the present disclosure.

The detailed description explains embodiments of the disclosure, together with advantages and features, by way of example with reference to the drawings.

### DETAILED DESCRIPTION

Disclosed herein are embodiments of an automated system for modeling and effectuating restoration of services due to power outages. The system includes software which uses an Agent-Based Model (“ABM”) simulation system to optimize and effectuate power restoration efforts after major storm events. The technology integrates real-world utility infrastructure data, historical outage data, and sophisticated algorithms to simulate the behaviors and decision-making processes of repair crews. Among other things, key features of the ABM include: multi-shift crew scheduling, dynamic routing, probability adjustments for repair time estimations, and real-time validation against actual restoration curves of historical storms. The output from the ABM may be used to guide and effectuate efficient restoration efforts in real-time.

Generally, the ABM includes a set of computer executable instructions stored on non-transitory machine readable media. The instructions provide for functionality as set forth herein.

Generally, the ABM pertains to software designed for managing, monitoring, and optimizing operations within an electrical transmission and distribution (“T&D”) network. The ABM integrates centralized and localized computing resources, uses Application Programming Interfaces (“APIs”) for interoperability, and may be developed using modular, scalable programming frameworks. The ABM is structured to support extensibility for future enhancements, seamless system integrations, and adaptation to evolving industry standards.

The ABM system includes functionality for estimating time to power outage restoration. The ABM may simulate a range of activities associated with power outage restoration including, for example, crew behavior, crew movement, and crew actions during the restoration process.

The ABM system may account for real-world constraints, thereby enhancing the real-time value of the guidance provided to restoration crews and resources.

The ABM enhances power restoration planning and execution following major storm events by creating a detailed virtual environment where work crews (agents) dynamically respond to power outages across a geographic region, incorporating actual utility infrastructure and historical outage data. The ABM employs algorithms to simulate real-world crew behaviors and decision-making processes through a multi-shift work schedule (e.g., morning, evening, and night crew shifts). The ABM integrates multiple critical components, e.g., a spatial-temporal distance matrix for optimal crew routing, dynamic probability adjustments for repair time estimations, and a hybrid strategy system that balances immediate safety concerns (like first responder calls) and high-impact outages affecting large numbers of customers. The ABM accounts for various real-world constraints, including crew fatigue, travel time variations during storm conditions, repair duration uncertainties, and geographic accessibility challenges. The ABM processes historical OMS data to generate accurate predictions of restoration times and crew requirements. The ABM implements an adaptive time-step mechanism that adjusts simulation granularity based on event dynamics, while continuously comparing simulated results against actual restoration curves for validation and refinement. The comprehensive approach of the ABM enables utilities to optimize resource allocation, improve response strategies, and enhance communication accuracy with customers during major storm events.

The ABM may implement a dynamic multi-shift crew scheduling system that realistically models the transition between morning, evening, and night shifts, reflecting actual utility operations during major storm events. The hybrid strategy of the ABM for resource allocation dynamically balances spatial efficiency and customer impact, with a unique threshold-based approach that prioritizes emergency response in the initial storm hours before transitioning to optimal restoration strategies. This adaptive approach is evident in the ability of the ABM to simultaneously manage multiple agents working on complex repair scenarios, including the strategic pairing of crews for high-priority or challenging repairs.

The ABM models of crew behavior incorporate multiple real-world factors, including progressive fatigue effects that influence repair times and efficiency, variable travel times that account for storm conditions and time of day, and repair durations based on historical data following a lognormal distribution. The ABM achieves geographic optimization through a sophisticated distance matrix calculation system that determines optimal crew routing while accounting for accessibility constraints and road conditions. The integration with historical OMS data enables the ABM to generate accurate predictions based on past storm experiences, while dynamic probability adjustments continuously refine repair time estimations as conditions evolve during the restoration period.

As discussed herein, “Artificial intelligence” (“AI”) provides systems capable of performing tasks that typically require human intelligence. These tasks include learning from experience, understanding language, recognizing patterns, solving problems, and making decisions.

As discussed herein, a “reinforcement learning” refers to a computational process configured to select actions in order to influence one or more measurable outcomes. The reinforcement learning agent is trained using one or more reward signals derived from interactions by an agent of the reinforcement learning model with its environment. The reinforcement learning agent may comprise one or more constraints.

As discussed herein, a “graph neural network” refers to a neural network that operates on data organized as a graph. The graph includes a collection of “nodes” (entities) connected by “edges” (relationships). The graph neural network learns by passing information along the edges between the nodes.

As discussed herein, a “utility restoration process” refers to a process that comprises a series of repairs to components of a utility grid which were damaged during a storm.

As discussed herein, a “trouble spot” refers to each damaged component of the utility grid and/or each location where the storm caused an issue which impedes the utility restoration process (e.g., a downed tree blocking a road).

As discussed herein, a “restoration curve” refers to a graph which a number of customers who are impacted by the damaged components of the utility grid over time.

As discussed herein, a “geographic region” refers to the region within which the utility restoration process occurs. The geographic region may be defined by a service area of the utility grid, an impact area of the storm, or a border. The geographic region may be divided into any number of “sub-regions.” Additionally or alternatively, the geographic region may be divided into a plurality of towns.

As discussed herein, an “input layer” refers to a component of a computational model through which the computational model receives inputs.

As discussed herein, a “work crew” refers to a team of tradespeople who work together to complete repairs during the utility restoration process.

As discussed herein, an “area work center” refers to a staging area for the work crew(s).

As discussed herein, an “agent” refers to a state machine representation of a work crew. “Work crew” and “agent” may be used interchangeably herein when referring to how a computational model may manipulate the actions of the work crew based on the representative agent of said work crew.

As discussed herein, a “work crew assignment” refers to a trouble spot which a work crew was assigned to repair. A work crew assignment may be provided to the agent representing the work crew.

As discussed herein, an “agent-based model (ABM)” refers to a computational model that develops an optimized solution to the utility restoration process by simulating activities of the work crew via the agent.

As discussed herein, “normalization” or “normalizing” refers to the process through which a series of values are standardized to a standard scale (e.g., between zero and one).

As discussed herein, a “weight” is a scalar which represents a relative priority of a particular item. A weight is usually calculated relative to other weights. A weight may be stored in a vector such that each dimension of the vector represents a different relative weight.

As discussed herein, “social vulnerability” refers to a social vulnerability of a particular sub-region or town of the geographic region.

Commercial applications where the ABM is particularly useful may include utility storm response planning, where the ABM may be used to optimize crew deployment and routing strategies and improve resource allocation for faster restoration times. The ABM may also be useful for training and scenario planning and to provide emergency response teams with realistic simulation-based training. The ABM may additionally be useful for real-time decision support, where the ABM may be used to integrate with Outage Management Systems (“OMS”) for real-time progress tracking and strategy refinement. The ABM may also be utilized for performance benchmarking, where the ABM may be used to analyze historical data to enhance restoration protocols. Additionally, the ABM may be used for regulatory compliance and reporting, for example, to generate performance metrics for utility companies to meet regulatory requirements. The ABM could also be used for risk assessment and support mitigation planning for extreme weather events.

The ABM has several advantages over current practice/methods/tools, including optimized resource allocation by dynamically balancing between immediate emergency responses and high-impact restorations, unlike traditional systems that may not prioritize effectively, as well as providing accurate predictions of crew requirements and repair times, ensuring better use of available resources. The ABM also exhibits improved efficiency and reduced restoration times including sophisticated routing algorithms and adaptive strategies minimize crew travel and repair times compared to manual planning methods. The ABM further exhibits enhanced computational efficiency that reduces simulation run times from 24-48 hours to 1-2 hours, enabling last-minute adjustments during storm events. Real-world operational realism included in the ABM incorporates factors such as crew fatigue, travel conditions, and repair duration uncertainties, providing more realistic and actionable insights than current static or less-detailed modeling tools. Enhanced decision-making real-time validation and comparison with actual restoration curves enable continuous adjustment of strategies during ongoing operations. The ABM also allows utilities to simulate various storm scenarios for better preparation and improved decision-making. The ABM may be integrated with historical data such that the ABM utilizes historical OMS data for accurate predictions and strategy validation. The ABM is capable of detailed tracking of crew activities, restoration progress, and resource utilization supports performance benchmarking and regulatory compliance. Customizability: adjustable parameters, such as crew availability and repair time distributions, allow utilities to tailor the ABM to specific storm scenarios and geographic conditions. The ABM is also capable of handling major storm events with 15,000-20,000 outages, supporting large-scale operations that traditional methods may struggle with. The ABM enables utilities to test and refine restoration strategies virtually, reducing the need for costly field trials and minimizing downtime. The ABM also improves accuracy in communicating estimated restoration times to customers, enhancing transparency and customer satisfaction.

Potential users of the ABM may include electric utility companies, which could use the ABM to manage and streamline storm recovery operations. Emergency response coordinators could also use the ABM for effective resource allocation and prioritization of critical infrastructure. Regulatory agencies and consultants could use the ABM to assess utility performance and support long-term planning. Insurance companies could use the ABM for risk modeling and planning related to storm damages.

A strength of the ABM lies in the customizable parameters, allowing a user to adjust variables such as crew availability, repair time distributions, inaccessibility probabilities, and multi-agent collaboration factors to match different storm scenarios and operational conditions. The ABM provides real-time comparison capabilities between simulated and actual restoration curves, enabling continuous validation and adjustment of restoration strategies. This comprehensive monitoring system includes detailed logging of crew activities, restoration progress, and resource utilization, providing valuable insights for both immediate operational decisions and long-term planning improvements.

Advantageously, the ABM enables utility providers and operators to optimize crew deployment strategies before and during storm events. This feature of the ABM provides accurate predictions of restoration times for better customer communication, helps identify resource requirements and optimal crew allocation and reduces restoration times through intelligent agent routing and task prioritization. Further, this feature of the ABM supports decision-making during large-scale power outages, allows utilities to test different restoration strategies without real-world implementation, accounts for real-world constraints and variations in repair scenarios and facilitates better emergency response planning and resource management.

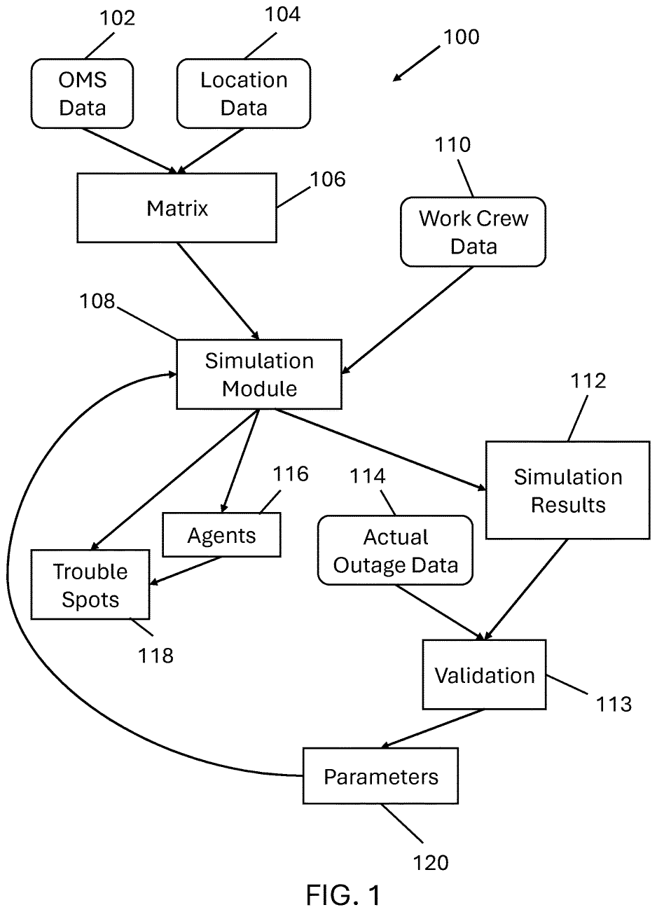

In the embodiment of FIG. 1, an Agent-Based Model (“ABM”) 100 is shown. The ABM 100 is computational model which generates an agent-based simulation of utility restoration after a storm. Generally, a utility grid includes a plurality of components. Each component of the plurality of components may be responsible for distributing the utility (e.g., electricity) to customers that utilize the utility grid. In the wake of a storm, utility outages may be caused by mechanical damage to some of the plurality of components of the utility grid, such as downed power lines, damaged utility poles, flooded transformers, downed tree, and other sources of damage that will be readily apparent to a person of ordinary skill in the art. The location of each damaged component is known as a trouble spot. To restore the utility grid to working order, a work crew is sent to physically repair damage at each trouble spot. The work crew may be one of a plurality of work crews. The number of trouble spots may exceed the number of work crews available. Accordingly, the ABM 100 is used to optimize management of the work crews to optimize the utility restoration process.

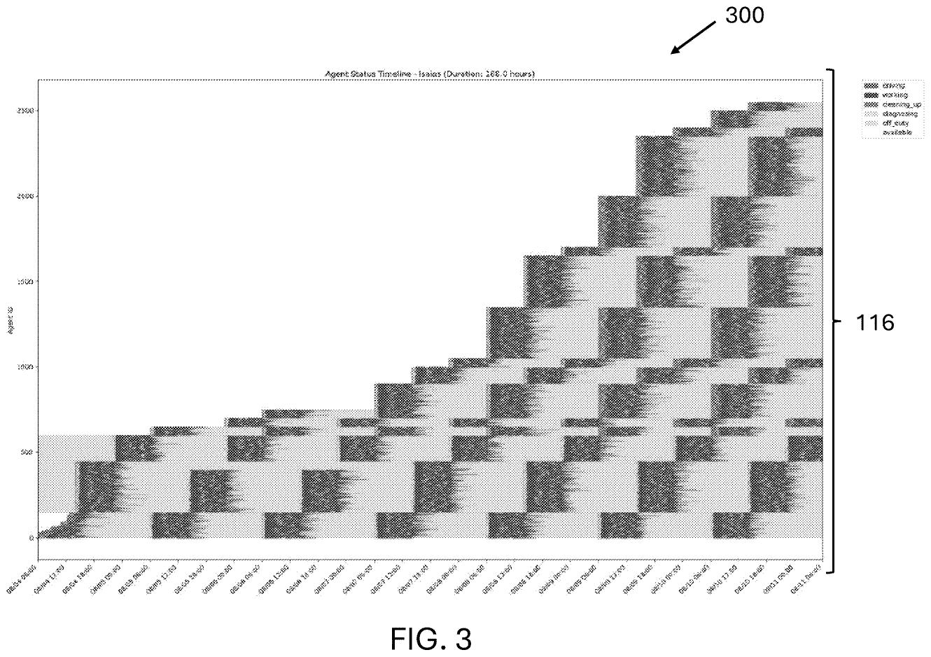

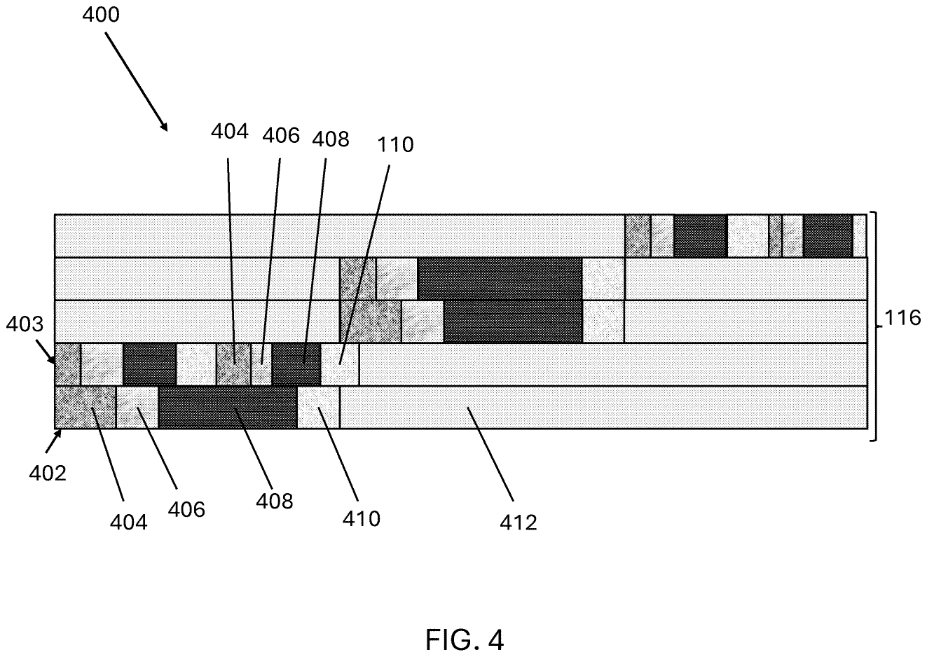

In some embodiments, the ABM 100 simulates individual work crews of a plurality of work crews as agents (see FIGS. 3 and 4). The ABM 100 simulates the movements and actions of each individual agent to develop an efficient solution to agent distribution, as will be described in greater detail herein. The ABM 100 determines how to distribute each work crew across a geographic region affected by the storm. In addition, the ABM 100 determines the order in which trouble spots should be repaired by the plurality of work crews.

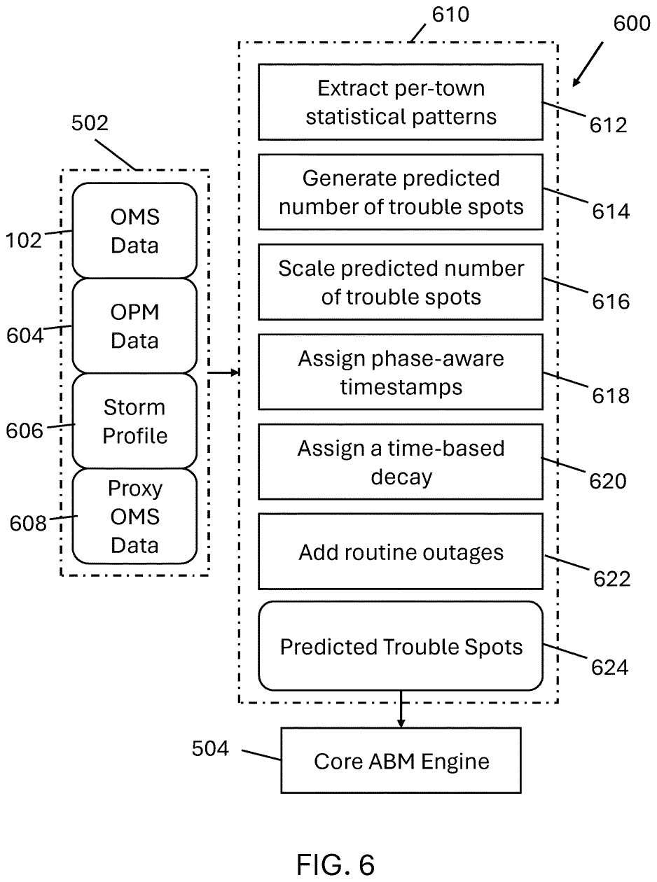

The ABM 100 may be utilized in advance based on forecast information of an expected storm. As will be described in greater detail in relation to FIG. 6, the ABM 100 may utilize the forecast information as well as historical storm data to estimate a number of trouble spots, and the locations thereof. In addition, a user may provide a preferred restoration completion time. In response, the ABM 100 may output a proposed number of work crews, a proposed geographic distribution of the work crews, and a proposed agenda of trouble spots for each work crew (see FIGS. 3 and 4). In some embodiments, the ABM 100 is utilized between 24 to 72 hours ahead of an expected arrival time of the storm.

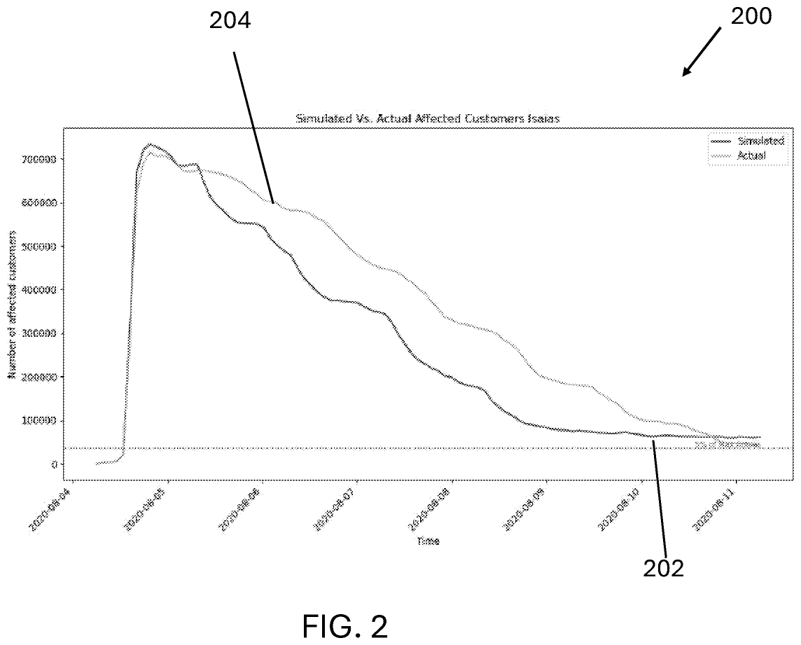

The ABM 100 may be utilized in real-time as work crews are actively deployed in the geographic region. In this scenario, the ABM 100 may receive current outage data including a number of trouble spots, the cause of each respective trouble spot, and the respective location of each trouble spot. The ABM 100 may also receive data representing the plurality of work crews, including a location for each respective work crew. In response, the ABM 100 may output an expected restoration curve (see FIG. 2) and a proposed agenda of trouble spots for each work crew (see FIGS. 3 and 4).

As shown in FIG. 1, the ABM 100 receives outage management system (“OMS”) historical data 102. The OMS data 102 represents historical storm outage data for the geographic region. The historical storm outage data is categorized on a per-storm basis. In other words, the OMS data 102 includes an outage dataset for each storm recorded in the OMS data 102. For each storm, the OMS data 102 stores a profile of the storm along with data representative of a plurality of utility grid outages recorded during the storm. The ABM 100 additionally receives location data 104 representing the starting location of each work crew of the plurality of work crews. In some embodiments, the starting location of the plurality of work crews may be centralized at a plurality of area work centers that are located within and around the geographic region affected by the storm.

In the ABM 100, the OMS data 102 and the location data 104 are processed to generate a matrix 106 representing distances between work crews and trouble spots. The matrix 106 is provided to the main simulation module 108 of the ABM 100. Additionally, work crew data 110, which includes the number of work crews and a respective working schedule of each work crew, is provided to the main simulation module 108.

The main simulation module 108 may create and manage a plurality of agents 116, with each agent of the plurality of agents 116 representing each work crew of the plurality of work crews. These agents 116 are created based on the location data 104 and the work crew data 110. Therefore, each agent 116 may be represented by a starting location (e.g., an area work center), a working schedule, and an activity state. The main simulation module 108 may also generate a registry of trouble spots 118. Each agent 116 may be assigned to repair one or more trouble spots listed in the registry of trouble spots 118. As the trouble spots are repaired, either at a simulated pace or in real-time, the main simulation module 108 may update the registry of trouble spots 118. If additional trouble spots are discovered, the ABM 100 may add the additional trouble spots to the registry of trouble spots 118 and assign an agent 116 to the additional trouble spot. Once a trouble spot is repaired, the main simulation module 108 may mark the respective trouble spot in the registry of trouble spots 118 as being repaired.

As the storm impacts the affected geographic area, the simulation results 112 may be validated against actual outage data 114 using a validator module 113. The actual outage data 114 is representative of reported damage to a plurality of components of the utility grid. The actual outage data 114 may be the actual restoration curve 204.

The validator module 113 compares the simulation results 112 against the actual outage data 114. As additional outage data 114 is obtained for local observation, improved data visibility, and customer reporting, the simulation results 112 may be continuously validated against the additional outage data 114. This validation may occur continuously until the restoration is complete and all trouble spots are repaired. This validation process may also be used to improve the simulation capabilities of the main simulation module 108, as will be described in further detail herein. The validation process may also be used to adjust a sensitivity of the main simulation module 108 by tuning a plurality of parameters 120. The plurality of parameters 120 may be simulation configuration parameters that control at least one behavior of the ABM 100 during a simulation. For example, the plurality of parameters 120 may include a mean repair time distribution, a maximum repair time, inaccessibility probability functions, and travel time multipliers.

In some embodiments, the validator module 113 uses a Symmetric Mean Absolute Percentage Error (SMAPE) metric. The SMAPE metric is compared against a threshold value. If the SMAPE metric exceeds the threshold value, then the validator module determines a parameter of the plurality of parameters 120 which influenced the discrepancy. In some embodiments, the validator module 113 uses a parameter sensitivity analysis engine to systematically vary the plurality of parameters 120 across multiple simulations of the ABM 100. In each simulation, the validator module 113 produces a SMAPE metric and compares the SMAPE metric to the threshold value to compare the simulation with the actual restoration curve 204. Based on each comparison, the validator module 113 can tune the plurality of parameters 120.

Based on the OMS data 102, the location data 104, the matrix 106, and the work crew data 110, the main simulation module 108 may simulate the impact of the storm and generate simulation results 112. The simulation results 112 may include expected outage data including expected locations of trouble spots. In addition, the simulation results 112 may include expected repair times for each trouble spot, which are aggregated to form an expected restoration curve 202 (see FIG. 2). Furthermore, the simulation results 112 may include an expected activity timetable 300 for the plurality of work crews (see FIGS. 3 and 4).

In some embodiments, a computing architecture of the ABM 100 follows a hybrid model that combines centralized computing with localized processing. Centralized computing is typically implemented through a central server or cloud-based platform, which provides overarching control, data aggregation, advanced analytics, and decision support functionalities.

In some embodiments, this central system handles critical tasks such as integration with Supervisory Control and Data Acquisition (“SCADA”) systems, outage management, load forecasting, and predictive maintenance analytics. These centralized operations are generally hosted on high-availability physical servers, virtual machines, or cloud infrastructure such as Amazon Web Services, Microsoft Azure, or Google Cloud Platform. Complementing this, localized computing may be deployed through edge devices positioned at substations, transformers, and various distribution nodes. These local controllers may perform real-time data acquisition and immediate control operations, thereby minimizing latency and ensuring that essential functions continue even during communication disruptions. Typical localized devices include Programmable Logic Controllers (“PLCs”), Remote Terminal Units (“RTUs”), and Intelligent Electronic Devices (“IEDs”). Communication between centralized and localized components may be facilitated via secure data exchange protocols such as MQTT, DNP3, IEC 61850, and RESTful APIs operating over TCP/IP networks.

To ensure interoperability across diverse hardware and software environments, the system may incorporate both standardized and custom APIs. RESTful and SOAP APIs enable integration with Enterprise Resource Planning (“ERP”) systems, Geographic Information Systems (“GIS”), Customer Information Systems (“CIS”), and other enterprise-level platforms. Additionally, industry-specific APIs may provide interfaces compatible with energy market platforms, regulatory reporting systems, and Distributed Energy Resource Management Systems (“DERMS”). Custom API gateways may allow for the extension of system functionality by third-party developers, facilitating integration with Internet of Things (“IoT”) devices and mobile workforce management applications. All API communications may be secured using protocols such as OAuth 2.0, API keys, and SSL/TLS encryption to safeguard data integrity and privacy.

In some embodiments, the software is developed using modular, object-oriented, and service-oriented programming paradigms to promote flexibility and scalability. Backend development may leverage languages such as Java, Python, C#, or Go, utilizing frameworks like Spring Boot, .NET Core, or Django. For user interface development, languages like JavaScript and TypeScript may be employed alongside frameworks such as React, Angular, or Vue.js to deliver intuitive web-based dashboards and control panels. Data processing and analytics capabilities may be enhanced through tools like Apache Kafka for stream processing, Apache Spark for big data analytics, and TensorFlow for machine learning applications. Data storage solutions include both relational databases, such as PostgreSQL, MySQL, and Microsoft SQL Server, and NoSQL databases like MongoDB and Cassandra to manage unstructured data from IoT sources. The system architecture may supports cloud-native technologies, including containerization with Docker and orchestration using Kubernetes, to enable scalable deployment across varied environments.

In some embodiments, an alternative computing architecture of the ABM 100 may include a Python application which runs on a Linux HPC cluster or a local workstation. The alternative computing architecture may utilize standard Python libraries such as NumPy, pandas, scikit-learn, PyTorch, PyTorch Geometric, and Stable-Baselines3. The alternative computing architecture may also utilize a web interface such as Streamlit.

In some embodiments, alternative approaches to the computing architecture of the ABM 100 may include fully cloud-based architectures in place of hybrid models, serverless computing for event-driven processing, or the adoption of low-code and no-code platforms for organizations seeking rapid deployment with minimal custom software development. Communication protocols such as OPC UA or Modbus TCP/IP may be used as substitutes depending on legacy system compatibility. Blockchain technology may be incorporated to provide immutable logging of critical grid events. Commercially available systems demonstrating similar architectures and functionalities include OSIsoft PI System, GE Grid Software, Siemens Spectrum Power, and Schneider Electric EcoStruxure Grid.

These and other alternative computing architectures of the ABM 100 may be realized by a person of ordinary skill in the art without departing from the scope of the present disclosure.

Referring now to FIG. 2, a restoration curve graph 200 is shown according to some embodiments of the present disclosure. The restoration curve graph 200 displays the expected restoration curve 202 in comparison with an actual restoration curve 204. The actual restoration curve 204 represents the utility restoration process that occurred after tropical storm Isaias impacted Connecticut in 2020. The expected restoration curve 202 was generated by the ABM 100 in response to historical data of tropical storm Isaias. In the example shown in FIG. 2, the OMS data 102, the location data 104, the work crew data 110, and the outage data 114 were all derived from historical data of the utility restoration process following tropical storm Isaias. As shown in FIG. 2, the expected restoration curve 202 indicates that utilizing the ABM 100 during the utility restoration process following tropical storm Isaias may have resulted in a reduced restoration timeline compared to the actual restoration timeline.

Referring now to FIG. 3, the activity timetable 300 generated by the ABM 100 is shown according to some embodiments of the present disclosure. The activity timetable 300 shows a number of agents 116 on the vertical axis, and a timeline on the horizontal axis. In the activity timetable 300, activities of each agent 116 are represented by a horizontal bar. Each horizontal bar is divided into several shaded sections based on the activities of the respective agent 116. These shaded sections are described in greater detail in reference to FIG. 4. The activity timetable 300 shows all activities of all of the agents 116 during the utility restoration process.

Generally, the plurality of agents 116 (and by extension, the work crews that the agents 116 represent) may be divided into three shifts: morning, afternoon, and night. Each shift may last approximately eight hours. As shown in FIG. 3, the morning shift may begin at 6 AM. The afternoon shift may begin at 2 PM. The afternoon shift may begin at 10 PM. Digital agents 116 are generally only identified as active in the activity timetable 300 during their respective shift.

As shown in the activity timetable 300, the number of agents 116 may increase (or decrease) throughout the utility restoration process. This increase in the number of agents 116 may occur as additional work crews are hired to participate in the utility restoration process.

Each additional work crew is represented by an additional agent 116. Each additional agent 116 may be assigned into one of the morning shift, the afternoon shift, or the evening shift. In some embodiments, the additional work crew may be mutual aid work crews hired from outside the geographic area.

In the embodiment shown in FIG. 4, a simplified exemplary timetable 400 is shown according to some embodiments of the present disclosure. Each row represents a agent of the plurality of agents 116. In the simplified exemplary timetable 400, each row spans a period of 24 hours. Each row is divided into a plurality of shaded sections. Each shaded section represents an activity of the work crew that is represented by the respective agent. For example, the bottommost work crew agent 402 conducts the following activities during the 24-hour period represented in the exemplary timetable 400. The first activity 404 includes driving to a location of a respective trouble spot. The second activity 406 includes setting up equipment and diagnosing an issue causing the trouble spot in order to determine a repair strategy for fixing the trouble spot. The third activity 408 includes conducting the repair strategy to fix the trouble spot. The fourth activity 410 includes cleaning up equipment and any leftover repair materials. The fifth activity 412 includes the downtime or off-shift time of the work crew. Generally, the first activity 404, the second activity, 406, the third activity 408, and the fourth activity 410 may be referred to as “on-shift” or “active” time which occurs during the approximate hours designated by the shift assigned to the agent.

As shown in the simplified exemplary timetable 400, the off-shift time for each work crew is staggered to provide ongoing repair work on the plurality of trouble spots. In some instances, as shown in regard to the second-from-bottom work crew agent 403, the work crew may repeat activities during their on-shift time. Repeat activities may occur when a repair at a first trouble spot is brief and additional time remains before the agent ends the shift. The ABM 100 may then assign the agent to a second trouble spot during the same on-shift. For example, the second-from-bottom work crew agent 403 repeats the first activity 404, the second activity, 406, the third activity 408, and the fourth activity 410. Thus, the second-from-bottom work crew agent 403 repaired two trouble spots during the on-shift time of the second-from-bottom work crew agent 403.

Generally, any non-downtime activities are constrained to the eight-hour working shift of the respective work crew. However, the ABM 100 may determine that assigning a work crew overtime to conduct an extended repair strategy may be an efficient or cost-effective strategy. If so, then the timetable (e.g. activity timetable 300 or simplified exemplary timetable 400) would reflect this overtime by including a smaller amount of downtime in fifth activity 412 (see, for example, the second-from-bottom work crew agent 403).

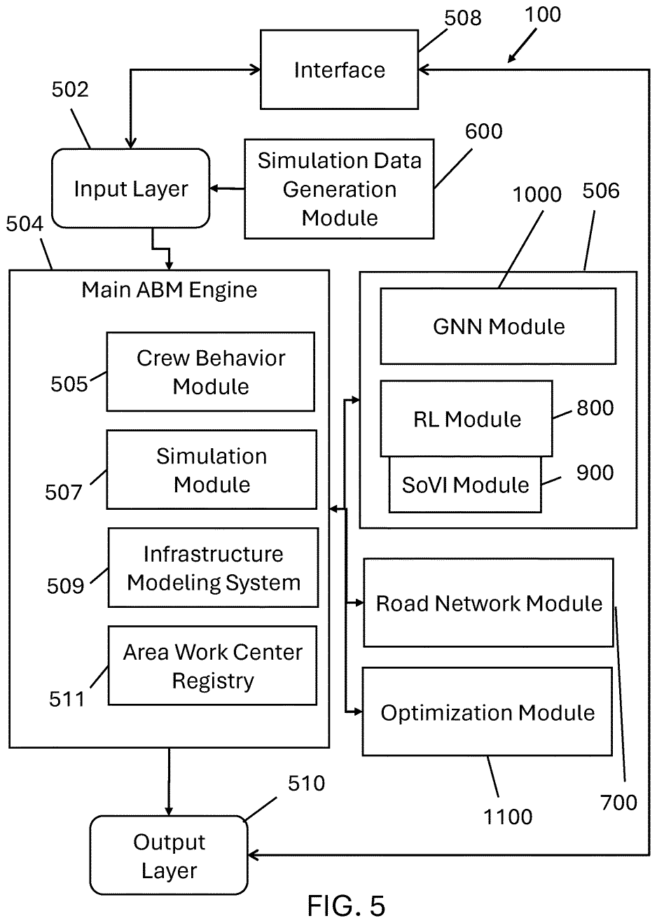

In the embodiment shown in FIG. 5, the ABM 100 may be sub-divided into several component modules. ABM 100 may include an input layer 502 which includes a framework for receiving data inputs such as the OMS data 102, the location data 104, the work crew data 110, and the actual outage data 114. Other data inputs that may be received via the input layer 502 will be described in greater detail below. In some embodiments, the input layer 502 includes a simulation data generation module 600. In some embodiments, a user may engage with the input layer using an interface 508. The interface 508 may be a computer which is communicably coupled to the ABM 100. In some embodiments, the interface 508 may be operated via a browser and/or a dedicated software application. The interface 508 may be implemented at a computing station, or in segments across multiple computing stations.

ABM 100 may include a core ABM engine 504. In some embodiments, the core ABM engine 504 is the main simulation module 108. The core ABM engine 504 receives the data inputs from the input layer 502. The core ABM engine 504 may include or be connected to several discrete components including a road network module 700, a machine learning module 506, a Social Vulnerability Index (“SoVI”) module 900, and an optimization module 1100. Each of these components may be integrated into and/or communicate with the core ABM engine 504.

In some embodiments, the machine learning module 506 is separated into a reinforcement learning (“RL”) module 800 and a graph neural network (“GNN”) module 1000. In some embodiments, the SoVI module 900 is a component of the RL module 800.

In some embodiments, the core ABM engine 504 includes a crew behavior module 505 which models each work crew as a respective agent of the plurality of agents 116. The crew behavior module 505 represents each agent of the plurality of agents 116 as a state machine. An activity state of each agent may represent an activity of the agent (e.g., the first activity 404, the second activity 406, the third activity 408, the fourth activity 410, or the fifth activity 412). The crew behavior module 505 may categorize each agent as a line agent or a tree agent. Line agents represent work crews that perform electrical repairs. Tree agents represent work crew that clear debris or vegetation. The crew behavior module 505 may assign each agent to a shift based on the work crew data 110. The crew behavior module 505 may track a current location of each agent. The crew behavior module 505 may also assign each agent to a home area work center to which the agent should return at the end of on-shift time. In some embodiments, the crew behavior module may also track whether a particular agent is available for a new trouble spot assignment based on the activity state and the shift of the particular agent. The crew behavior module 505 may also reassign a particular agent to a different home area work center to modify a distribution of the plurality of agents 116 across the geographic region. The crew behavior module may also track a fatigue of each agent based on a number of hours worked by the work crew represented by the agent. The crew behavior module 505 may combine individual agents into a crew class containing multiple individual agents. The crew behavior module 505 continuously updates and tracks the state(s) of each agent in the plurality of agents 116. The crew behavior module 505 provides this state data to the RL module 800, the SoVI module 900, and the GNN module 1000.

In some embodiments, the core ABM agent 504 also maintains an area work center registry 511. The area work center registry 511 stores data which describes a state of each area work center. The area work centers may be evenly distributed across the geographic region. Each area work center may be assigned responsibility for a particular sub-region of the geographic region. Accordingly, the area work center registry 511 may store the number of trouble spots located within the particular sub-region of each area work center. In addition, the area work center registry 511 may store a number of active crews that are assigned to each respective area work center. Generally, each agent will remain within the sub-region of the home area work center of that particular agent, unless the agent is re-assigned to a different area work center by the crew behavior module 505. The area work center registry 511 may also track a length of a deferred queue of trouble spots associated with the respective area work center.

In some embodiments, the core ABM engine 504 includes an infrastructure modeling system 509. The infrastructure modeling system may receive predicted outage data generated by the simulation data generation module 600 and/or may receive the actual outage data 114. For example, the infrastructure modeling system 509 may utilize the simulation data generation module 600 output if the ABM 100 is being used to simulate a future storm. Alternatively, the infrastructure modeling system 509 may utilize the actual outage data 114 if the ABM 100 is being used in real-time to manage the utility restoration process. Based on the simulation data generation module 600 and/or the actual outage data 114 infrastructure modeling system 509 categorizes each trouble spot based on a type of damage located at the trouble spot. For example, the infrastructure modeling system 509 may store each of the plurality of damaged components stored in the actual outage data as a trouble spot in the registry of trouble spots 118. In some embodiments, the infrastructure modeling system 509 may categorize the trouble spot as tree damage, utility pole damage, transformer damage, or substation damage. The infrastructure modeling system 509 may also determine an expected maximum repair time based on the categorization of the type of damage. For example, tree damage repairs may be capped at 8-12 hours, utility pole replacement may be capped at 24 hours, transformer replacement may be capped at 36 hours, and substation restoration may be capped at 72 hours If additional trouble spots are discovered, the infrastructure modeling system 509 may add the additional trouble spots to the registry of trouble spots 118. The infrastructure modeling system 509 may continuously update the registry of trouble spots 118. In some embodiments, the registry of trouble spots 118 represents each trouble spot based on a plurality of attributes. For example, in some embodiments, the infrastructure modeling system 509 may track a number of customers affected by each trouble spot in the registry of trouble spots 118. In some embodiments, the infrastructure modeling system 509 may track a SoVI score of each trouble spot in the registry of trouble spots 118. In some embodiments, the infrastructure modeling system 509 may track an accessibility score for each trouble spot in the registry of trouble spots 118. The accessibility score represents potential obstructions (e.g., fallen trees) that may cause a work crew to encounter difficult accessing the trouble spot. In some embodiments, the infrastructure modeling system 509 may store a continuation status of each trouble spot in the registry of trouble spots 118 (e.g., if a work crew began repair work on a trouble spot but the shift ended before the work crew could complete the repair). In some embodiments, the infrastructure modeling system 509 may store a deferral status of each trouble spot in the registry of trouble spots 118. The infrastructure modeling system 509 may output the registry of trouble spots 118 to the simulation module 507, the RL module 800, the SoVI module 900, and the GNN module 1000.

In some embodiments, the core ABM engine 504 includes a simulation module 507. The simulation module 507 is configured to process the outputs of the input layer 502, the crew behavior module 505, the infrastructure modeling system 509, the road network module 700, the RL module 800, the SoVI module 900, and the GNN module 1000. If the ABM 100 is being used to simulate the impact of a storm, then the simulation module 507 simulates the utility restoration process from an initial time to a finish condition based on the initial boundary conditions provided by the input layer 502. As the simulation module 507 simulates the utility restoration process, the core ABM engine 504 may execute a plurality of successive iterations as the core ABM engine 504 solves toward the finish condition. In some embodiments, each successive iteration corresponds to an hour of utility restoration process time. In some embodiments, the finish condition is a 90% restoration of power to utility customers. If the ABM 100 is being used in real-time during the utility restoration process, then the simulation module 507 utilizes real-time data from the input layer 502 to construct and continuously update a parallel simulation that simulates the utility restoration from a current time in the utility restoration process to the finish condition. In some embodiments, the simulation module 507 iterates a new parallel simulation every hour. In some embodiments, when the ABM 100 is being used to simulate the impact of a storm on the geographic area, the simulation module 507 may determine a preferred number of agents for the plurality of agents 116. The preferred number of agents may be the number of work crews hired before the storm impacts the geographic region.

In some embodiments, the simulation module 507 assigns each agent of the plurality of agents 116 to each of the trouble spots. As each work crew repairs each trouble spot, the simulation module 507 may track a repair status of each repair. The repair status of each repair may be determined based on the activity (e.g., first activity 404, second activity 406, third activity 408, fourth activity 410, or fifth activity 412) of the agent assigned to the repair.

Because the number of trouble spots may outnumber the number of agents, the simulation module 507 may maintain a queue of deferred trouble spots. When a crew completes a task, the simulation module 507 may assign the corresponding agent to a trouble spot from the queue of trouble spots. The simulation module 507 may account for increased travel times of each respective agent of the plurality of agents 116 based on a time-dependent factor that models road conditions during the utility restoration process.

Because some trouble spots may be more complicated to repair than others, the simulation module 507 may assign a crew class to trouble spots with complicated repairs.

In some embodiments, the simulation module 507 may track whether a repair status has extended for a duration exceeding a threshold. If so, then the simulation 507 may flag that respective trouble spot and agent for investigation to determine whether additional resources are needed.

The simulation module 507 may output the expected restoration curve 200 and/or the expected activity timetable 300. The core ABM engine 504 may provide outputs generated by the simulation module 507 (e.g., the expected restoration curve 200 and/or the expected activity timetable 300) to an output layer 510. Other outputs which may be provided by the output layer 510 will be described in greater detail herein. The output layer 510 may display the results on the interface 508 for the user to view the results.

### Simulation Data Generation Module

Referring now to FIG. 6, some embodiments of the simulation data generation module 600 are described in greater detail. FIG. 6 shows a processing pipeline 610 of the simulation data generation module 600. The simulation data generation module 600 is used when the ABM 100 is used to predict the impact of a storm on the geographic region. The simulation data generation module 600 produces data representative of a number of predicted trouble spots per town in the geographic region impacted by the storm, and statistical patterns such as possible failure mode of trouble spots, how many customers are impacted by a trouble spot, timing of a failure of the trouble spot, and spatial clustering of the trouble spots.

The simulation data generation module 600 may receive three primary inputs via the input layer 502: the OMS data 102, outage prediction model (“OPM”) data 604, and a storm profile 606. The OMS data 102 may include historical outage records including customer impact counts, timestamps of trouble spot failures, locations of trouble spots, and causes of trouble spot failures. The OMS data 102 is available for any storm which occurred after 2005. The OPM data 604 may include town-level predictions of trouble spots based on meteorological parameters of a storm. More specifically, the OPM data 604 may be the likely number of trouble spot outages per town. The storm profile 606 may include a meteorological prediction of the storm as well as a likely growth potential of the storm. The simulation data generation module 600 may additionally receive proxy OMS data 608. The proxy OMS data 608 is synthetic data representative of the historical storm data for storms which occurred before OMS data 102 became available in 2005.

Once the OMS data 102, the OPM data 604, and the storm profile 606 are provided to the simulation data generation module 600, the processing pipeline 610 of the simulation date generation module 600 may be activated. The processing pipeline 610 may execute several processing activities. First, in activity 612, the simulation data generation module 600 extracts per-town statistical patterns from the OMS data 102. Then, in activity 614, the simulation data generation module 600 generates a predicted number of trouble spots in the utility system using the OMS data 102. In some embodiments, the simulation data generation module 600 may use the storm profile 606 to identify an analogous storm stored in the OMS data 102. In activity 616, the predicted number of trouble spots is scaled by storm-specific growth factors included in the storm profile 606. Next, in activity 618, the simulation data generation module 600 assigns phase-aware timestamps with magnitude-dependent placement to each predicted trouble spot. In other words, the simulation data generation module 600 accounts for the location of each predicted trouble spot relative to an epicenter of the storm to determine a likelihood and a potential damage magnitude of each trouble spot. The simulation data generation module 600 also accounts for potential follow-on failures that may occur after the storm has passed (e.g., if a weakened tree falls on a transformer 3 hours after the storm has subsided). In activity 620, the simulation data generation module 600 assigns a time-based decay to an incidence of trouble spots after the storm has passed. In other words, the simulation data generation module 600 reduces the likelihood of additional post-storm trouble spots as time passes after the storm subsides. In activity 622, the simulation data generation module 600 adds routine outages which may have occurred regardless of the storm.

After the processing activities are executed, the simulation data generation module 600 outputs a spreadsheet of predicted trouble spots 624. The spreadsheet of predicted trouble spots 624 includes a location and a time of failure for each predicted trouble spot. The spreadsheet of predicted trouble spots 624 is provided back to the core ABM engine 504. The infrastructure modeling system 509 may use the spreadsheet of predicted trouble spots 624 to generate the registry of trouble spots 118.

### Road Network Module

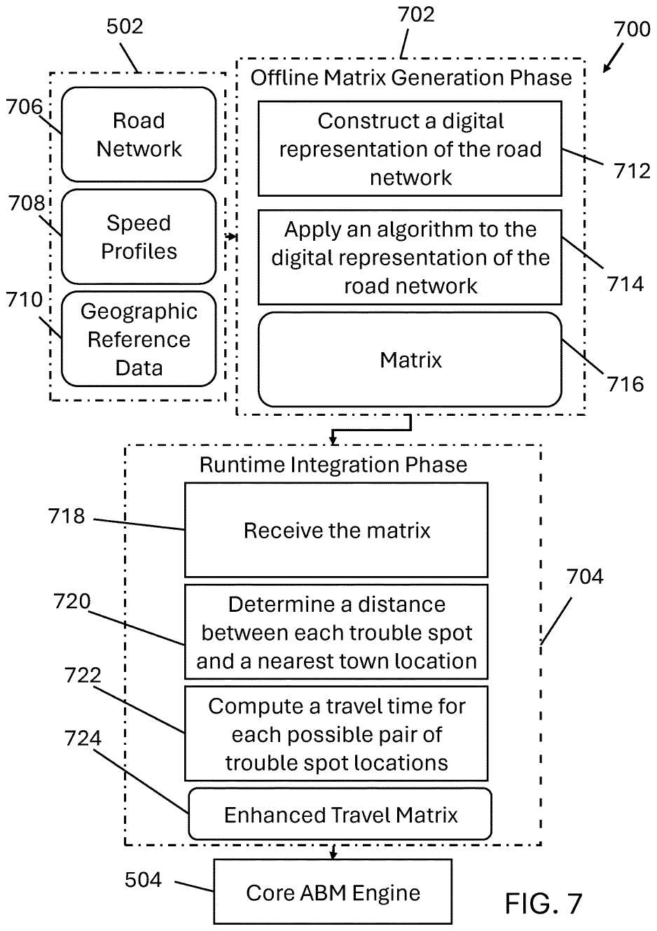

Referring now to FIG. 7, some embodiments of the road network module 700 are described in greater detail. FIG. 7 shows a processing pipeline of the road network module 700. The road network module 700 may have two distinct operational phases: an offline matrix generation phase 702 and a runtime integration phase 704.

First, the road network module 700 executes the offline matrix generation phase 702. The offline matrix generation phase 702 receives a road network 706 of the geographic region from the input layer 502. The road network 706 may be a digital map representation of a plurality of roads of the geographic region. In some embodiments, the road network 706 is received from OpenStreetMap. Then, the offline matrix generation phase 702 may receive speed profiles 708 from the input layer 502. The speed profiles 708 may represent a travel speed of each individual road of the plurality of roads represented within the road network 706. The speed profiles 708 may also represent an expected storm impact modifier that may reduce the travel speed of each road. The reduced travel speed may be representative of a likely travel speed along the respective individual road while the storm impacts the geographic region. The offline matrix generation phase 702 may also receive geographic reference data 710 from the input layer 502. The geographic reference data 710 may include a location and a boundary of each town location in the geographic region. The geographic reference data 710 may also a location of each area work center located in or proximate the geographic region. In some embodiments, the geographic reference data 710 represents each town location and each area work center location as a node.

In activity 712, the offline matrix generation phase 702 constructs a digital representation of the road network of the geographic region based on the road network 706 and the speed profile 708. The digital representation of the road network is mapped relative to the geographic reference data 710 such that the digital representation of the road network represents connections between each town location and/or each area work center. Then, in activity 714, the offline matrix generation phase 702 applies an algorithm to the digital representation of the road network to calculate the shortest path between each town location and/or each area work center location stored in the geographic reference data 710. In some embodiments, the algorithm is the Dijkstra Shortest Path algorithm. The algorithm may account for variations in travel speeds of each road such that the algorithm favors roads with a higher travel speed. The algorithm generates a matrix 716 which includes the shortest path between each pair of locations. The phrase “shortest path” refers to the path between each pair of locations that is likely to incur the least amount of travel time.

Second, the road network module 700 executes the runtime integration phase 704. The runtime integration phase 704 receives the matrix 716 from the offline matrix generation phase 702. The runtime integration phase receives the locations of each trouble spot (e.g., from either the registry of trouble spots 118) and calculates last-mile distances from the nearest area work center and/or town. In activity 718, the runtime integration phase 704 receives the matrix 716. Then, in activity 720, the runtime integration phase 704 determines a distance between each trouble spot location and a nearest town location or area work center location. In some embodiments, the runtime integration phase 704 accomplishes activity 720 by computing a Haversine great-circle distance from each trouble spot location to all of the town locations and area work center locations. Then, the runtime integration phase 704 selects the shortest distance. Next, in activity 722, the runtime integration phase 704 computes a hierarchical three-segment travel time for each possible pair of trouble spot locations. The hierarchical three-segment travel time may be calculated based on three components: 1) the distance between the first trouble spot of the pair and the nearest location to the first trouble spot location (calculated in activity 720); 2) the shortest path between the nearest location to the first trouble spot location and the nearest location to the second trouble spot location (from matrix 716); and 3) the distance between the nearest location to the second trouble spot location and the second trouble spot location (calculated in activity 720). If both the first trouble spot location and the second trouble spot location share the same nearest location, the travel time may be calculated based solely on the Haversine great-circle distance between the first trouble spot location and the second trouble spot location. The runtime integration phase 704 then outputs an enhanced travel matrix 724 which may be a paired travel time matrix between all locations (e.g., each town location, each area work center location, and each trouble spot location).

The road network module 700 provides the enhanced travel matrix 724 to the core ABM engine 504. In some embodiments, the enhanced travel matrix 724 is only updated when additional trouble spots are added to the registry of trouble spots 118.

Accordingly, the road network module 700 combines pre-computed road travel times between known locations (e.g., the geographic reference data 710) with local Haversine legs to determine a total distance a work crew will need to travel from an area work center or town to a trouble spot. This approach achieves an accurate road network at a minimal computational cost. More specifically, the matrix 716 is only computed once, then loaded each time a total distance computation is needed. Thus, ABM 100 computation times are reduced.

### RL Module

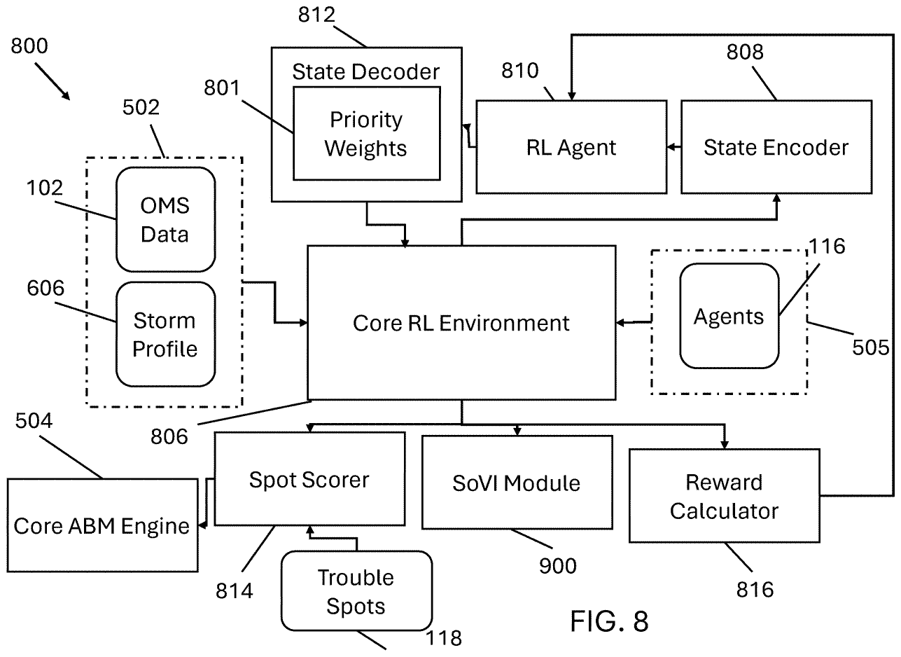

Referring now to FIG. 8, some embodiments of the RL module 800 are described in greater detail. FIG. 8 shows a system architecture of the RL module 800. Generally, the RL module 800 is responsible for assigning a global priority to each trouble spot. In doing so, the RL module 800 balances several factors that may increase or decrease a priority of a particular candidate trouble spot. Because the number of trouble spots is often greater than the number of work crews, the RL module 800 may also determine when a candidate trouble spot repair should be deferred to the queue of deferred trouble spots.

Every hour of the utility restoration process or simulation thereof, the RL module observes a restoration state of the utility restoration process and outputs priority weights 801 that dictate how work crews are dispatched to trouble spots. The RL module 800 may receive four inputs. One, the RL module 800 may receive the OMS data 102. Two, the RL module may receive the storm profile 606. Three, the RL module 800 may receive the plurality of agents 116 from the crew behavior module 505. Four, the RL module 800 may receive the priority weights 801 that were previously calculated by the RL module 800 during a previous iteration. If the simulation is in a first iteration, no previously calculated priority weights 801 exist. Accordingly, in the first iteration, the RL module 800 receives a pre-storm state of the ABM 100 simulation. In some embodiments, the pre-storm state indicates that all existing trouble spots in the registry of trouble spots 118 are unrepaired, all work crews are at their home area work centers, and zero time has elapsed since the simulation was initiated.

At each iteration, a core RL environment 806 receives the inputs for the RL module 800. The core RL environment 806 then generates a state analysis of utility restoration process in the ABM 100 simulation based on the OMS data 102, the storm profile 606, the plurality of agents 116, and, for successive iterations of the ABM 100, the previous priority weights 801. In some embodiments, the core RL environment 806 is a Gymnasium environment. The core RL environment 806 provides the state analysis to a state encoder 808. In some embodiments, the state analysis stores data representing the number of customers who are not receiving the utility, which trouble spots have already been repaired, and the location and state of each agent of the plurality of agents 116. The state encoder 808 encodes the state analysis into an observation vector. The state encoder 808 then provides the observation vector to an RL agent 810. The RL agent 810 may then generate normalized priority weights for each trouble spot by applying a softmax transformation to the observation vector. The RL agent 810 may produces weights that sum to 1.0. The RL agent 810 then outputs a vector of real-valued numbers. The vector may be continuous 5-dimensional vector. The RL agent 810 provides the vector to a state decoder 812.

The state decoder 812 calculates the priority weights 801 based on the vector and provides the priority weights 801 back to the core RL environment 806. In some embodiments, the state decoder 812 applies a softmax transformation to convert the five raw values into normalized priority weights that sum to 1.0. For example, if the RL agent 810 outputs the continuous 5-dimensional vector [2.1, 1.5, 0.8, 1.2, 3.0], the state decoder 812 would transform this continuous 5-dimensional vector via softmax into priority weights 801 having approximate values [0.22, 0.12, 0.06, 0.09, 0.51], where each value represents the relative importance of a corresponding dispatch dimension. The state decoder 812 may output a single vector of global priority weights 801 which apply to each trouble spot and each of the plurality of agents 116.

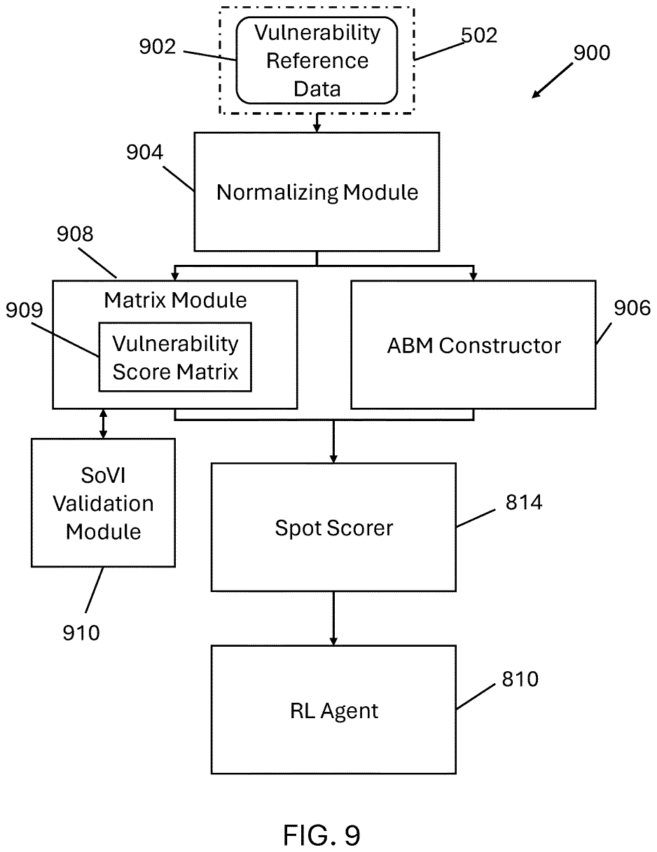

In some embodiments, the priority weights 801 includes several dispatch dimensions. For example, the priority weights 801 may include a spatial weight dimension that penalizes a travel distance to each candidate trouble spot. The priority weights 801 may also include a customer weight dimension which weights each candidate trouble spot based on a number of customers impacted by the trouble spot. For example a damaged substation may impact a greater number of customers than a downed power line, because the damaged substation may prevent the utility from reaching an entire sub-region of the utility grid, whereas the downed power line may impact a single neighborhood. The priority weights 801 may additionally include a vulnerability weight dimension that prioritizes trouble spots that are located in sub-regions of the geographic region that have a high social vulnerability. The vulnerability weight will be described in greater detail in relation to FIG. 9. The priority weights 801 may also include a continuation weight dimension that prioritizes trouble spots at which a previous work crew already began repair work (e.g., if a shift ended before a work crew assigned to the shift completed the repair). The priority weights 801 may further include a queue management weight dimension, which prioritizes candidate trouble spots which were previously deferred. In the example above, the approximate values of the priority weights are organized as follows: spatial weight, customer weight, vulnerability weight, continuation weight, deferred weight.

Once the priority weights 801 are provided back to the core RL environment 806, the core RL environment 806 provides the priority weights 801 to a spot scorer 814. The spot scorer 814 is a fifth-dimensional scoring function that ranks a priority of each trouble spot based on the priority weights 801, the OMS data 102, the storm profile 606, the plurality of agents 116, and the state analysis.

In some embodiments, the spot scorer 814 add each of the priority weights 801 for each trouble spot together to determine an aggregate priority weight for the respective trouble spot. The aggregate priority weight for each trouble spot may be normalized. The normalized aggregate priority weight may be used to rank the priority of each trouble spots from highest to lowest. For example, a first trouble spot having a normalized aggregate priority weight of 0.8 may be given a higher priority ranking than a second trouble spot having a normalized aggregate priority weight of 0.6. As a result, the first trouble spot may be repaired first.

In some embodiments, the spot scorer 814 applies the spatial weight of the priority weights 801 to the travel distance from a respective work crew location to each candidate trouble spot location. The spot scorer also applies customer, equity, continuation, and deferred weights of the priority weights 801 to attributes of each candidate trouble spot (e.g., the affected customer count, the SoVI score, the continuation status, and the deferral status) that are independent of crew location. The scoring function normalizes each dimension across the current set of candidate trouble spots for each work crew.

In some embodiments, the spot scorer 814 may output a ranked list of trouble spots which ranks the plurality of trouble spots based on the normalized aggregate priority weight of each trouble spot. In some embodiments, the spot scorer 814 may then assign each agent of the plurality of agents 116 to a trouble spot based on the ranked list of trouble spots. In some embodiments, the spot scorer 814 generates a repair assignment for each work crew. In some embodiments, the spot scorer 814 only assigns active agents to trouble spots. In some embodiments, the spot scorer 814 may defer a trouble spot if not enough active agents are available to assign an agent to each trouble spot. In some embodiments, the spot scorer 814 may assign multiple agents to a single trouble spot if the trouble spot requires an extensive or complicated repair. If multiple agents were accidently assigned to a single trouble spot, the spot scorer 814 may re-assign redundant agents to different trouble spots based on the remaining trouble spots in the ranked list of trouble spots. After the first iteration of the ABM 100, the core ABM engine 504 may store the ranked list of trouble spots as registry of trouble spots 118. Once a trouble spot has been repaired, the spot scorer 814 may ignore the repaired trouble spot(s) in the registry of trouble spots 118.

In some embodiments, the spot scorer 814 may be included in the simulation module 507.

The core RL environment 806 then communications with a reward calculator module 816. The reward calculator module 816 computes a scalar reward at each hourly decision step based on restoration progress. The scalar reward is calculated as the ratio of customers which received restored the utility in the current iteration compared to a peak number of customers without the utility. The scalar reward is positive when progress is made and zero when no customers are restored. The reward calculator module 816 rewards a terminal bonus when the simulation reaches the finish condition. The scalar reward incentivizes the RL agent 810 to maximize a rate of customer restoration at every decision step, with a cumulative reward over a simulation reflecting the overall speed and completeness of the restoration process.

The core RL environment 806 also communicates with the SoVI module 900, which will be described in greater detail in relation to FIG. 9. The SoVI module 900 is integrated into the RL module 800 to adjust the priority weights 801 based on social vulnerability of each town in the geographic region.

Once the iteration of the RL module 800 is complete, the core RL environment 806 advances the ABM 100 simulation by one hour.

In some embodiments, the RL module 800 is trained using a Proximal Policy Optimization (“PPO”) algorithm. The PPO algorithm training process utilizes simulated storm restoration episodes based on OMS data 102 from previous storms (e.g., tropical storm Isaias). During each simulated episode, the RL agent 810 interacts with the core RL environment 806 for approximately 216 iterations. This number of iterations approximately corresponding to a 9-day restoration timeline. At each step, the RL agent 810 outputs priority weights 801, the spot scorer 814 assigns agents and dispatches work crews accordingly, and the reward calculator module 816 provides a reward signal based on the number of customers restored during that step. The PPO algorithm updates a neural network policy of the RL agent 810 to increase the probability of weight selections that led to higher cumulative rewards. The training process is repeated over 500 episodes (~148,000 total timesteps), after which the RL agent 810 converges to a policy that consistently outperforms rule-based dispatch strategies.

Essentially, the RL module 800 learns optimal work crew dispatch priority weighting through simulated storm restoration episodes. The RL module 800 utilizes the priority weights 801 to assign a ranking to each trouble spot.

Referring now to FIG. 9, some embodiments of the SoVI module 900 are described in greater detail. FIG. 9 shows an exemplary architecture of the SoVI module 900 integrated within the RL module 800. The SoVI module 900 is intended to improve equitable access to utilities following a utility outage caused by a storm. By including vulnerability data in the global trouble spot priority ranking process (described in reference to FIG. 8), the RL module 800 balances restoration efforts for high-density areas with critical infrastructure with vulnerable regions that might not otherwise be prioritized during the utility restoration process.

The SoVI module 900 receives vulnerability reference data 902. The vulnerability reference data 902 includes population-adjusted equity-based vulnerability data for each town within the geographic region. In some embodiments, the vulnerability reference data 902 is a structured dataset including SoVI scores for each town in the geographic region. In some embodiments, each entry in the vulnerability reference data 902 includes: (a) a town name; (b) a raw SoVI score, which is the sum of z-scores from six principal component analysis (PCA) factors derived from Census 2020 demographic variables including income, education, age, disability, language, and housing characteristics. In some embodiments, a value of the SoVI score is representative of how vulnerable a particular town is. For example, a town with a −7 score is less vulnerable than a two with a +6 score. Each score may be represented with a rational number.

Once the SoVI module 900 receives the vulnerability reference data 902, the SoVI module 900 utilizes a SoVI normalizing module 904 to normalize the raw vulnerability reference data 902. The SoVI normalizing module 904 provides the normalized vulnerability reference data to an ABM constructor 906, which loads the normalized vulnerability reference data and assigns a normalized vulnerability score to each trouble spot based on the town in which the trouble spot is located. For example, if a trouble spot located within a boundary of a town having a high normalized vulnerability score then the trouble spot is assigned a vulnerability score corresponding to the normalized vulnerability score of the town. In some embodiments, the core RL environment 806 invokes the ABM constructor 906 at the beginning of each training episode or simulation. The SoVI normalizing module 904 also provides the normalized vulnerability reference data to a matrix module 908. The matrix module 908 stores the normalized vulnerability score of each trouble spot in the vulnerability score matrix 909. The vulnerability score for each trouble spot may also be stored as the SoVI score stored in the registry of trouble spots 118. The matrix module 908 provides the trouble spot vulnerability score matrix 909 to the spot scorer 814. The spot scorer 814 accounts for the vulnerability score of each trouble spot when ranking the priority of each trouble spot in the ranked list of trouble spots. Additionally, the spot scorer 814 may account for the vulnerability score of each trouble spot when assigning each agent of the plurality of agents 116 to a trouble spot based on the ranked list of trouble spots The spot scorer 814 provides the most recent ranking of each of the trouble spots (including the vulnerability score of each trouble spot) to the RL agent 810 on each successive iteration of the RL module 800. The RL agent 810 may use the trouble spot vulnerability scores to calculate the vulnerability dimension weight when calculating the priority weights 801.

In some embodiments, the SoVI module 900 includes a SoVI validation module 910 that confirms that every trouble spot in the simulation receives a valid vulnerability score. The SoVI validation module 910 may also calculate summary statistics of the trouble spot vulnerability scores to confirm plausibility. For example, the SoVI validation module 910 may confirm that, on average, trouble spots in high-vulnerability towns received greater vulnerability scores than trouble spots in low-vulnerability towns.

The efficiency of the RL module 800 including the SoVI module 900 was analyzed relative to three alternative RL modules that did not include SoVI modules: an equal weights RL module that balanced each of the priority weights 801, a RL module that disproportionately favored the customer weight in the priority weights 801, and a RL module that disproportionately favored the spatial weight in the priority weights 801. The RL module 800 including the SoVI module 900 performed better than all three alternative RL modules that did not include SoVI modules. In particular, the simulated utility restoration process directed RL module 800 including the SoVI module 900 reached the finish condition with a simulated restoration timeline of 194.1 hours plus or minus 2.6 hours. In contrast, the next-best simulation (the equal weights RL module) reached the finish condition with a simulated restoration timeline of 196.8 hours plus or minus 1.5 hours. Accordingly, the RL module 800 including the SoVI module 900 exhibited a more efficient restoration timeline.

In some embodiments, the RL agent 810 developed a 3-phase equity adaptation strategy. The RL agent 810 generally prioritized the vulnerability weight dimension early in the utility restoration process. Then, the RL agent 810 moved to a transition stage with more balanced priority weights 801. Finally, the RL agent 810 prioritized the queue management weight dimension until the utility restoration process was complete. The 3-phase equity adaptation strategy operated in approximately 8-hour oscillations that align with crew shift schedules.

### GNN Module

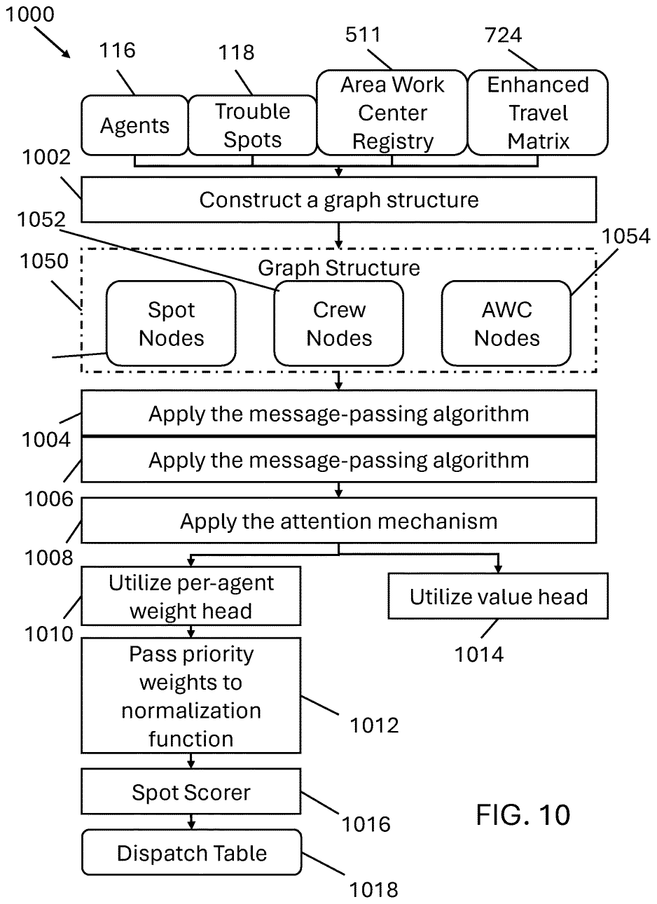

Referring now to FIG. 10, some embodiments of the GNN module 1000 are described in greater detail. FIG. 10 shows a processing pipeline for the GNN module 1000, according to some embodiments. The GNN module 1000 produces per-agent priority weights for work crew dispatching. The per-agent priority weights are tailored to a local restoration state of the work crew represented by the respective agent of the plurality of agents 1116.

First, the GNN module 1000 receives a current state of all trouble spots from the registry of trouble spots 118. The GNN module 1000 also receives the current state of each agent of the plurality of agents 116 from the crew behavior module 505. The GNN model 1000 additionally receives area work center registry 511. The GNN module 1000 further receives the enhanced travel matrix 724 from the road network module 700, which provides precomputed travel times between all locations in the geographic region.

Then, in activity 1002 GNN module 1000 constructs a heterogenous graph structure 1003 which represents a current state of the utility restoration process based on the registry of trouble spots 118, the plurality of agents 116, the area work center registry 511, and the enhanced travel matrix 724.

The graph structure 1003 may include each trouble spot as a spot node of a plurality of spot nodes 1050. Each spot node of the plurality of spot nodes 1050 may include the parameters of the current state of the associated trouble spot. In some embodiments, each spot node of the plurality of spot nodes 1050 may include nine features based on the current state of the trouble spot: normalized latitude, normalized longitude, number of affected customers, SoVI score, estimated repair time, whether a previous crew has already worked on this trouble spot, crew size required, whether the trouble spot is currently inaccessible, and how many hours the trouble spot has been waiting for service.

The graph structure may additionally include each agent of the plurality of agents 116 as a crew node of a plurality of crew nodes 1052. Each crew node of the plurality of crew nodes 1052 may include the parameters of the current state of the respective agent, which were supplied to the GNN module 1000 via the current state of the plurality of agents 116. In some embodiments, each crew node of the plurality of crew nodes 1052 includes six features: normalized latitude, normalized longitude, crew specialization code, hours remaining in current shift, whether the crew is currently active/available, and whether this is a multi-crew assignment.

The graph structure 1003 may also include each area work center as an AWC node of a plurality of AWC nodes 1054. Each AWC node of the plurality of AWC nodes 1054 may include the parameters of the current state of each area work center. In some embodiment, each AWC node of the plurality of AWC nodes 1054 may include four features: normalized latitude, normalized longitude, number of remaining unrepaired spots assigned to the respective area work center, and number of currently active crews operating from the respective area work center.

The graph structure 1003 also stores several different edge types: spot-to-spot spatial edges, crew-to-spot eligibility edges, spot-to-AWC membership edges, and crew-to-AWC assignment edges.

The spot-to-spot spatial edges may connect trouble spots that are geographically near each other. For example, the spot-to-spot spatial edges may connect spot nodes within a predefined radius of one another. These spot-to-spot spatial edges enable the GNN module 1000 to understand a local damage density based on geographic clustering of trouble spots.

The crew-to-spot eligibility edges may connect each crew node of the plurality of crew nodes 1052 to the spot nodes which the respective work crew is eligible to repair, based on distance constraints and operational availability (e.g., dictated by the respective work crew specialization code, hours remaining in current shift, and whether the respective work crew is currently active/available). In some embodiments, work crew eligibility to repair a respective trouble spot (represented by a spot node) is based on the home area work center of the work crew. The work crew may be eligible to repair trouble spots located in the sub-region of the area work center. In some embodiments, work crew eligibility to repair a respective trouble spot is based on a radius extending from the home area work center of the work crew. The work crew may be eligible to repair trouble spots located in within the radius. In some embodiments, work crew eligibility to repair a respective trouble spot based on the home area work center of the work crew, and an adjacent area work centers located within a radius of the home area work center. The work crew may be eligible to repair trouble spots located within the sub-region of the home area work center or a sub-region of any area work center located within the radius.

The spot-to-AWC membership edges may connect each spot node of the plurality of spot nodes 1050 to the AWC node representing the area work center operationally responsible for the geographic zone within which the trouble spot is located. Additionally, the crew-to-AWC assignment edges may connect each crew node of the plurality of crew nodes 1052 to the AWC node representing the home area work center of the respective agent.

In activities 1004 and 1006, the GNN module 1000 utilizes two sequential layers of a message-passing algorithm that enables each node (irrespective of node type) to learn from each neighboring node. In some embodiments, the message-passing algorithm is GraphSAGE (Sample and Aggregate). In activity 1004, the GNN module 1000 applies the message-passing algorithm such that each node collects information from the immediate neighbor nodes of the respective node via the edges (irrespective of type) that connect the respective node to the immediate neighbor nodes. In activity 1006, the GNN module 1000 applies the message-passing algorithm such that each node collects information from the neighbors of the immediate neighbors of the node. The message passing algorithm may operate across the entire graph structure 1003. Because the message-passing algorithm may operate on the entire graph structure 1003, the GNN module 1000 operates on a global basis.

After activities 1004 and 1006, each crew node of the plurality of crew nodes 1052 includes a numerical representation that encodes the features of the respective crew node and the features of nearby spot nodes, the local damage density, and a local area work center context (e.g., the features of the nearest AWC node).

Because information is propagated between neighboring nodes in activities 1004 and 1006, the SoVI scores of each trouble spot are implicitly incorporated into the encoded numerical representation included in each crew node of the plurality of crew nodes 1052. As a result, the GNN module 1000 accounts for vulnerability imbalances between trouble spots.

In activity 1008, the GNN module 1000 applies a Graph Attention Mechanism (“GAT”) layer which applies an attention mechanism to the crew-to-spot connections. The attention mechanism enables the GNN module 1000 to learn which spot nodes should be prioritized for each crew node of the plurality of crew nodes 1052 based on factors like damage type compatibility, travel distance, and restoration urgency. The GAT includes a plurality of independent attention heads that determine a plurality of attention weights. In some embodiments, the plurality of independent attention heads includes four attention heads and the plurality of attention weights includes four attention weights. The attention weights represent which spot nodes are most important for each crew node of the plurality of crew nodes 1052. The attention weights are interpretable and therefore provide visibility into the decision-making process of the GNN module 1000.

In activity 1010, the GNN module 1000 utilizes a per-agent weight head to output a priority weight vector specific to each crew node of the plurality of crew nodes 1052. In other words, the priority weight vector is specific to each agent of the plurality of agents 116. The priority weight vector may be a 5-dimensional priority weight vector. The per-agent weight head may be a small neural network that develops the 5-dimensional priority weight vector for each crew node of the plurality of crew nodes 1052 based on the encoded numerical representation of each crew node and the attention heads. In some embodiments, the 5-dimensional priority weight vector includes the same five weight dimensions as the priority weights 801. However, the 5-dimensional priority weight vector is generated on a per-crew basis, whereas the priority weights 801 are generated globally and apply to all crews.

In activity 1012, the GNN module 1000 passes each priority weight vector to a normalization function. In some embodiments, the normalization function is a softmax normalization function. The normalization function ensures that the weights stored in the priority weight vector sum to approximately 1.0.

Generally, the GNN module 1000 generates the priority weight vector for each crew simultaneously.

The GNN module 1000 then passes each normalized priority weight vector to the spot scorer 814. In activity 1016, the spot scorer 814 may utilize the registry of trouble spots 118, the plurality of agents 116, the area work center registry 511, the enhanced travel matrix 724, and the normalized priority weight vectors to assign each agent to a trouble spot. More specifically, the GNN module 1000 provides the normalized 5-dimensional priority weight vectors for each agent, and the spot scorer 814 computes, for each agent, a composite score for each trouble spot. In some embodiments, the spot scorer 814 only computes a composite score for trouble spots which the respective work crew (represented by the respective agent) is eligible to repair. The spot scorer 814 then returns the highest scoring trouble spot as the next repair assignment for the agent. Once the spot scorer 814 has assigned a repair assignment to all agents of the plurality of agents 116, the corresponding work crews may be dispatched to the corresponding trouble spots repair assignment. The spot scorer 814 may only assign available agents. The spot scorer 814 then outputs a dispatch table 1018 that assigns each available crew to an optimal trouble spot.

In some embodiments, each repair assignment is recorded in the dispatch table 1018 before any work crew begins executing the assigned repair assignment.

In some embodiments, the spot scorer 814 computes the composite score using the enhanced travel matrix 724 to generate a spatial score of each trouble spot relative to each agent of the plurality of agents 116. The spot scorer 814 weights the spatial score with the spatial weight of the respective agent of the plurality of agents 116. The spot scorer 814 also uses the customer count for each trouble spot to generate an impact score of each trouble spot. The spot scorer 814 weights the impact score with the customer weight of the respective agent of the plurality of agents 116. The spot scorer 814 additionally uses the SoVI score to generate a vulnerability score for each trouble spot. The spot scorer 814 weights the vulnerability score with the vulnerability weight of the respective normalized priority weight vector of the respective agent of the plurality of agents 116. The spot scorer 814 also generates a continuation score for each trouble spot based on the continuation status of each trouble spot. The spot scorer 814 weights the continuation score with the continuation weight of the respective normalized priority weight vector of the respective agent of the plurality of agents 116. The spot scorer 814 additionally uses the deferred queue of trouble spots to generate a deferral score for each trouble spot. The spot scorer 814 weights the deferral score with the deferred weight of the respective normalized priority weight vector of the respective agent of the plurality of agents 116. The spot scorer 814 uses the weighted scores to calculate the composite score on a per-spot, per-crew basis.

In some embodiments, in activity 1014, the GNN module 1000 may utilize a value head to determine a prospective situation of the utility restoration process. The value head aggregates encoded information from all nodes (irrespective of node type) via mean pooling and processes it through a 2-layer neural network to produce a scalar value. The scalar value represents an expected reward, which correlates with an expected future state of the utility restoration process based on the current state of the utility restoration process. In other words, the scalar value represents how soon the utility restoration process may be completed. This scalar value is used to train the GNN module 1000 into optimizing for faster utility restoration processes.

In the RL module 800, the spot scorer 814 independently evaluates the same priority weights 801 for each agent. Because the spot scorer 814 evaluates candidate trouble spots for each crew based on the same priority weights 801, two agents may be assigned to the same trouble spot as the RL module 800 iterates through the plurality of agents 116. As a result, computation time is wasted when the RL module 800 determines that a later agent is a better fit for a respective trouble spot than an earlier agent. In contrast, the GNN module 1000 generates all per-crew vectors simultaneously and the spot scorer 814 operates independently for each agent of the plurality of agents 116. During this process, the spot scorer 814 may record work crew assignments in the dispatch table 1018 before each agent is assigned because the per-crew priority weights increase confidence that the first work crew selected for a particular trouble spot is the correct work crew. As a result, some experiments showed that the GNN module 1000 achieved the finish condition utility restoration timeline 11.6 hours faster than the RL module 800.

In some embodiments, the GNN module 1000 is trained using PPO, which is the same RL algorithm used to train the RL module 800. In some embodiments, the GNN module 1000 was trained based on historical data (e.g., OMS data 102) from a single storm, then applied to additional storms in a zero-shot generalization.

Early iterations of the GNN module 1000 did not utilize the enhanced travel matrix 724 as an input. In addition, early iterations of the GNN module 1000 bypassed the spot scorer 814. Instead, the early iterations of the GNN module 1000 directly outputted dispatch scores for each crew node/spot node combination. However, this approach forced the early iterations of the GNN module 1000 to learn spatial relationships based on the latitude and longitude features. Accordingly, utilizing the enhanced travel matrix 724 and spot scorer 814 improves the efficiency of the GNN module 1000.

### Optimization Module

Government agencies may penalize utility providers that fail to achieve utility restoration within a specific amount of time after a storm contacts the geographic region. The government agencies may issue monetary penalties to each utility provider that fails to achieve utility restoration within the specific amount of time. On the other hand, hiring additional work crews or requesting overtime from previously-hired work crews presents a financial burden for the utility provider. This relationship can be summarized using a cost-benefit framework. Accordingly, the optimization module 1100 solves for a minimum total cost based on this cost-benefit framework.

The cost-benefit framework includes two core components: a crew cost and a penalty cost. The crew cost may be based on work crew labor rates, number of hours worked by all work crews, equipment rates, number and rates of work crews hired from outside the geographic region, and an overhead percentage modifier. The penalty cost can be calculated based on local regulations, such as the Public Utilities Regulatory Authority (“PURA”) regulations in Connecticut.

The optimization module 1100 solves for a minimum value of the crew cost plus the penalty cost.

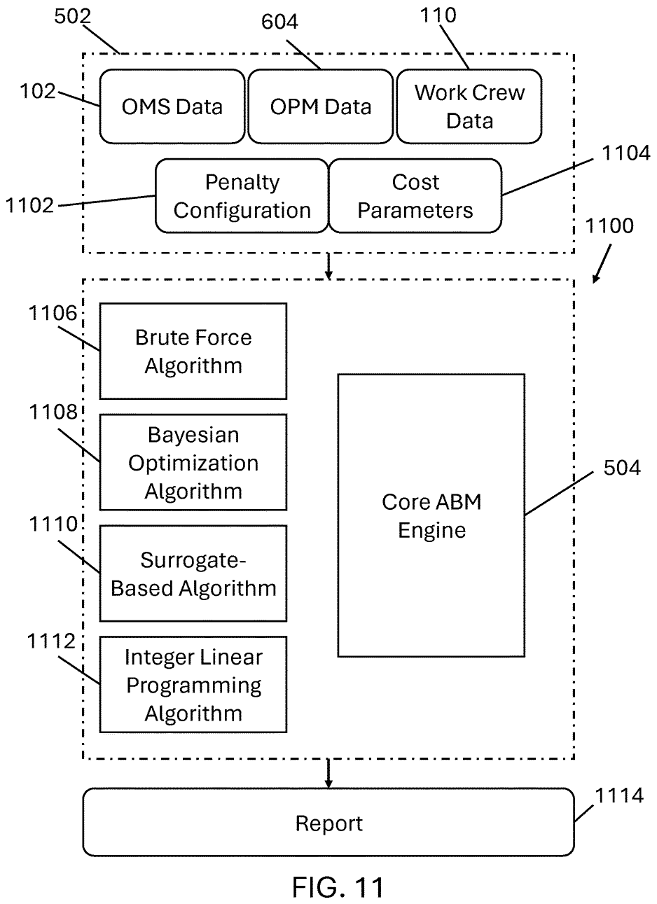

Referring now to FIG. 11, some embodiments of the optimization module 1100 are described in greater detail. FIG. 11 shows a processing pipeline for the optimization module 1100. Generally, the optimization module 1100 is configured to optimize a work crew allocation based on external factors such as work crew schedules, work crew costs, government penalties, storm characteristics, and outage data. The optimization module 1100 is intended to optimize a balance between regulatory compliance and work crew costs.

The optimization module 1100 receives several inputs from the input layer 502, including the OMS data 102, the OPM data 604, the storm profile 606, the work crew data 110, and a penalty configuration 1102. The penalty configuration 1102 may include information relating to the regulatory compliance framework and any monetary penalties associated with noncompliance. The optimization module 1100 may also optionally receive a plurality of cost parameters 1104. The cost parameters 1104 may include: an hourly crew labor rate (dollars per hour per crew), an equipment daily rate (dollars per day per crew), a mutual aid crew premium rate (a multiplier applied to external crews hired from outside the geographic region), and an overhead percentage applied to direct costs.

The optimization module 1100 may be configured to implement four different optimization algorithms based on the received inputs. Generally, each algorithm treats the core ABM engine 504 as a black box function. Before implementing any one of the four algorithms, the optimization module 1100 applies a single scale factor uniformly to a base crew schedule. Then, solving for the single scale factor, the optimization module 1100 identifies two solutions: (1) a cost-optimal value for the single scale factor that minimizes total cost, and (2) a compliance value for the single scale factor that minimizes total cost subject to the constraint that the length of the utility restoration process is less than or equal to a regulatory deadline. For example, the regulatory deadline may be 96 hours, which is based on the Connecticut PURA regulatory threshold.

Even with unlimited crews, the utility provider will likely be subject to some monetary penalties for delayed utility restoration in remote areas. Accordingly, the optimization module 1100 determines what the minimum regulatory penalty will be with unlimited crews.

The first algorithm is a brute force (grid search) algorithm 1106. The brute force algorithm 1106 evaluates a fixed number of evenly-spaced scale factor values of the single scale factor across a search range. For each scale factor value, the brute force algorithm 1106 constructs a crew schedule by multiplying a base crew schedule by the scale factor. The brute force algorithm 1106 then runs a complete ABM simulation, extracts restoration metrics, and computes the total cost of the utility restoration process. After evaluating all scale factor values, the algorithm identifies the scale factor value that produced the lowest total cost and the lowest-cost value that also satisfies the regulatory deadline. The brute force algorithm 1106 provides a complete visualization of the cost landscape across the entire scale factor range.

The second algorithm is a Bayesian optimization algorithm 1108. The Bayesian optimization algorithm 1108 iteratively builds a probabilistic model of the core ABM engine 504. Then, the Bayesian optimization algorithm 1108 utilizes uncertainty in the probabilistic model to determine select a scale factor value for the single scale factor. Specifically, the Bayesian optimization algorithm 1108 selects the next scale factor value that maximizes an Expected Improvement acquisition function, which balances exploitation (sampling near known good values) with exploration (sampling in regions of high uncertainty.

The third algorithm is a Surrgate-Based algorithm 1110. The Surrogate-Based algorithm 1110 may be a Random Forest algorithm. The Surrogate-Based algorithm is trained on initial black box samples to predict costs. In some embodiments, the Surrogate-Based algorithm 1110 trains a Random Forest regression model on an initial set of ABM simulation results. Each initial ABM simulation utilizes a different value for the single scale factor The Random Forest learns to predict the total cost of the utility restoration process as a function of the single scale factor. Once trained, the Surrgate-Based algorithm 1110 can predict costs for any scale factor value without running additional ABM simulations. The Surrgate-Based algorithm 1110 uses these predictions to identify a predicted cost-optimal scale factor, then validates the prediction by running the ABM simulation at the predicted optimal value. This approach is useful for what-if analysis because the smooth prediction surface enables rapid cost estimation across the entire scale factor range.

The fourth algorithm is an Integer Linear Programming (“ILP”) algorithm 1112. The ILP algorithm 1112 approximates the core ABM engine 504 as a piecewise-linear model. The ILP algorithm 1112 then solves a constrained optimization of the piecewise-linear model.

After the optimization module 1100 has received the inputs, the optimization module 1100 may select an algorithm based on a use case of the core ABM engine 504. The optimization module 1100 then calculates the scale factor. Next, the optimization module 1100 operates in a loop using the chosen algorithm to calculate and optimize costs for a given storm scenario. Generally, the optimization module 1100 optimizes toward a minimum total cost for the utility restoration process. The total cost may include a work crew cost and a monetary penalty cost. The optimization module 1100 operates in the loop until a stop condition is met. Finally, the optimization module 1100 generates a report 1114 which is provided to the output layer 510. The report 1114 may be accessed via the interface 508.

In some embodiments, the stop condition is based on the selected algorithm. For the brute force algorithm 1106, the loop terminates after all pre-specified scale factor values have been evaluated. For the Bayesian optimization algorithm 1108, the loop terminates after a configured number of iterations (typically 10 evaluations) or when the Expected Improvement falls below a convergence threshold, indicating that further sampling is unlikely to find a significantly better solution. For the Surrogate-Based algorithm 1110, the loop terminates after the validation simulation confirms the prediction of the surrogate model. For the ILP algorithm 1112, the loop terminates when the linear programming solver converges to the optimal solution of the piecewise-linear approximation.

In some embodiments, when a utility provider needs a complete cost landscape for regulatory audit documentation, the brute force algorithm 1106 is selected because the brute force algorithm 1106 evaluates the full range of scale factor values and produces a comprehensive visualization. When computational budget is limited and the utility provider seeks the most cost-efficient deployment, the Bayesian optimization algorithm 1108 is selected because the Bayesian optimization algorithm 1108 achieves near-optimal results with fewer ABM simulations. When the utility provider wants to explore hypothetical “what-if” scenarios (e.g., “what would happen if the number of work crews was increased by 20%?”), the Surrogate-Based algorithm 1110 is selected because the Surrogate-Based algorithm 1110 provides immediate cost predictions without additional simulation runs. When the utility provider has a fixed budget and needs to determine the best achievable restoration timeline within that budget, the ILP algorithm 1112 is selected because the ILP algorithm 1112 natively handles budget constraints.

The report 1114 may include a suggested number of work crews to be based out of each area work center for a duration of the utility restoration process, based on the single scale factor. The report 1114 may also include a suggested number of work crews per shift. The report 1114 may further include a suggested amount of overtime per crew. The report 1114 may additionally include expected monetary penalties based on the number of work crew. In some embodiments, the report 1114 may provide several different cost scenarios which correlate the number of work crews to the work crew cost and the monetary penalty cost.

The report 1114 may be provided to the core ABM engine 504. The main simulation module 507 may use the report 1114 to determine an accuracy of the results generated by the simulation module 507.

In the disclosure hereof any element expressed as a means for performing a specified function is intended to encompass any way of performing that function including, for example, a) a combination of circuit elements and associated hardware which perform that function or b) software in any form, including, therefore, firmware, microcode or the like as set forth herein, combined with appropriate circuitry for executing that software to perform the function. Applicants thus regard any means which can provide those functionalities as equivalent to those shown herein. No functional language used in claims appended herein is to be construed as invoking 35 U.S.C. § 112(f) interpretations as “means-plus-function” language unless specifically expressed as such by use of the words “means for” or “steps for” within the respective claim.

When introducing elements of the present invention or the embodiment(s) thereof, the articles “a,” “an,” and “the” are intended to mean that there are one or more of the elements. Similarly, the adjective “another,” when used to introduce an element, is intended to mean one or more elements. The terms “including” and “having” are intended to be inclusive such that there may be additional elements other than the listed elements. The term “exemplary” is not intended to be construed as a superlative example but merely one of many possible examples.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments described herein.

While the disclosure is provided in detail in connection with only a limited number of embodiments, it should be readily understood that the disclosure is not limited to such disclosed embodiments. Rather, the disclosure can be modified to incorporate any number of variations, alterations, substitutions or equivalent arrangements not heretofore described, but which are commensurate with the spirit and scope of the disclosure. Additionally, while various embodiments of the disclosure have been described, it is to be understood that the exemplary embodiment(s) may include only some of the described exemplary aspects. Accordingly, the disclosure is not to be seen as limited by the foregoing description, but is only limited by the scope of the appended claims.

What is claimed is:

1. A system for planning a utility restoration process in a geographic region, the system comprising:
an input layer, the input layer comprising:
outage management system (OMS) data, wherein the OMS data represents a plurality of utility grid outages recorded during at least one previous storm;
location data, wherein the location data represents a starting location of each work crew of a plurality of work crews;
work crew data, wherein the work crew data represents a number of work crews in the plurality of work crews, and a working shift of each respective work crew of the plurality of work crews; and
actual outage data, wherein the actual outage data represents a plurality of damaged components of the utility grid; and
a core agent-based model (ABM) engine, comprising:
a simulation module communicatively coupled to the input layer and configured to simulate the plurality of work crews as a plurality of agents, wherein:
each agent of the plurality of agents is a state machine which represents a respective work crew of the plurality of work crews, and
the simulation module assigns each agent of the plurality of agents to repair a damaged component of the plurality of damaged components using either a reinforcement learning module or a graph neural network module, and
the core ABM engine generates:
an expected activity timetable for the plurality of work crews that shows a plurality of activities that each agent takes to repair the plurality of damaged components, and
an expected restoration curve.

2. The system of claim 1, wherein the core ABM engine further comprises:
a crew behavior module which generates each agent of the plurality of agents based on the location data and the work crew data; and
an infrastructure modeling system which receives the actual outage data and generates a registry of trouble spots based on the actual outage data, wherein each damaged component is represented as a trouble spot stored in the registry of trouble spots.

3. The system of claim 2, wherein the crew behavior module is configured to:
combine work crews, and
reassign work crews between a plurality of area work centers located in the geographic region; and
the infrastructure modeling system is configured to:
maintain a deferred queue of unrepaired trouble spots in the registry of trouble spots.

4. The system of claim 2, further comprising a road network module comprising:
an offline matrix generation phase configured to:
receive a road network of the geographic region, a speed profile representing an travel speed of each road in the road network, and geographic reference data, the geographic reference data comprising:
a location and a boundary of each town located in the geographic region; and
a location of each area work center located in or proximate the geographic region; and
generate, using a Dijkstra Shortest Path algorithm, a shortest path between each town location and/or each area work center, wherein the shortest path between each town location and/or each area work center is stored in a matrix; and
a runtime integration phase configured to:
receive the matrix and the registry of trouble spots, wherein the registry of trouble spots stores a location of each of the plurality of damaged components; and
generate an enhanced travel matrix which identifies a shortest path between each area work center and each location stored in the registry of trouble spots.

5. The system of claim 1, further comprising:
an optimization module that solves for a single scale factor which minimizes a total cost for the utility restoration process, wherein the optimization module generates a suggested number of work crews based on the single scale factor.

6. The system of claim 5, wherein the optimization module is configured to:
incorporate a penalty cost based on local regulations, and
calculate a minimum regulatory penalty.

7. The system of claim 1, wherein the input layer further comprises:
a simulation data generation module, wherein the simulation data generation module generates a spreadsheet of predicted trouble spots based on:
the OMS data,
outage prediction model (OPM) data, and
a storm profile comprising meteorological prediction of a storm impacting the geographic region.

8. The system of claim 7, wherein the simulation data generation module is configured to select a previous storm from the OMS data based on the storm profile.

9. A reinforcement learning (RL) module for generating repair assignments for a plurality of work crews during a utility restoration process in a geographic region, the RL module comprising:
a core RL environment, wherein the core RL environment generates a state analysis of the utility restoration process based on:
a plurality of agents which each represent each of the work crews of the plurality of work crews as a state machine,
outage management system (OMS) data, wherein the OMS data represents a plurality of utility grid outages recorded during at least one previous storm,
a storm profile comprising meteorological prediction of a storm impacting the geographic region, and
a state of the utility restoration process;
a RL agent which receives the state analysis from the core RL environment via a state encoder, wherein the RL agent generates a vector of priority weights; and
a spot scorer which receives:
the vector of priority weights via a state decoder, and
a registry of trouble spots comprising a list of a plurality of trouble spots located in the geographic region, wherein the spot scorer assigns each agent of the plurality of agents to a trouble spot in the geographic region based on the vector of priority weights.

10. The RL module of claim 9, wherein the vector of priority weights is a comprising:
a spatial weight dimension that weights a travel distance an agent of the plurality of agents would need to travel to reach each trouble spot in the registry of trouble spots;
a customer weight dimension that weights a number of customers impacted by a respective trouble spot in the registry of trouble spots;
an vulnerability weight dimension that prioritizes respective trouble spots in the registry of trouble spots that are located in sub-regions of the geographic region that have a high social vulnerability;
a continuation weight dimension that prioritizes respective trouble spots at which a previous work crew already began repair work; and
a deferred weight that prioritizes candidate trouble spots which were previously deferred by the spot scorer.

11. The RL module of claim 10, further comprising:
a social vulnerability index (SoVI) module comprising:
a normalizing module that receives vulnerability reference data comprising a SoVI score for each town of a plurality of towns located in the geographic region, wherein the normalizing module normalizes the vulnerability reference data;
an agent-based model (ABM) constructor that assigns a vulnerability score to each trouble spot in the registry of trouble spots based on a proximity of the trouble spot to a nearest town of the plurality of towns, wherein the vulnerability score is based on the SoVI score of the respective nearest town from the vulnerability reference data; and
a matrix module that produces a vulnerability score matrix which includes the vulnerability score for each trouble spot, wherein:
the matrix module provides the vulnerability score matrix to the spot scorer, and
the spot scorer incorporates the vulnerability score of each trouble spot when assigning each agent of the plurality of agents to a trouble spot.

12. The RL module of claim 11, wherein the RL agent calculates the vulnerability weight based on the vulnerability score matrix.

13. A method for generating work crew assignments for a plurality of work crews during a utility restoration process of a geographic region using a graph neural network (GNN) module, the method comprising:
constructing a heterogenous graph structure comprising a plurality of nodes based on:
a registry of trouble spots comprising a list of a plurality of trouble spots located in the geographic region,
a plurality of agents which each represent each of the work crews of the plurality of work crews as a state machine,
an area work center registry which represents a plurality of area work centers located in the geographic region, and
a travel matrix comprising a list of travel times between each of the plurality of trouble spots and each of the plurality of area work centers;
applying a message-passing algorithm such that each node of the plurality of nodes collects information from at least one immediately neighboring node of the plurality of nodes;
applying the message passing algorithm such that each node of the plurality of nodes collects information from at least one neighboring node of the at least one immediately neighboring node of the plurality of nodes;
applying an attention mechanism to at least one crew-to-spot connection of the heterogenous graph structure;
utilizing a per-agent weight head to output a priority weight vector specific to each agent of the plurality of agents; and
utilizing a spot scorer to assign each agent of the plurality of agents to a trouble spot based on the priority weight vector of each agent of the plurality of agents.

14. The method of claim 13, wherein the attention mechanism includes a plurality of attention heads that determine a plurality of interpretable attention weights.

15. The method of claim 13, wherein the at least one spot node includes a Social Vulnerability Index (SoVI) score.

16. The method of claim 13, further comprising normalizing the priority weights using a normalization function before utilizing the spot scorer.

17. The method of claim 13, wherein the spot scorer generates a dispatch table that assigns each available crew to an optimal trouble spot, and wherein each work crew assignment is recorded in the dispatch table 1018 before any work crew begins executing the assignment.

18. The method of claim 13, wherein the spot scorer assigns each agent of the plurality of agents to a trouble spot by computing a composite score for each trouble spot based on the registry of trouble spots, the plurality of agents, the area work center registry, the travel matrix, and the priority weight vector of each agent of the plurality of agents.

19. The method of claim 13, further comprising:
aggregating, using a value head, encoded information from the plurality of nodes via mean pooling; and
processing, using a neural network, the encoded information to produce a scalar value of an expected reward.

20. The method of claim 13, wherein the GNN module is trained on OMS data from a single storm, then the GNN module is applied to additional storms in a zero-shot generalization.
